(19) United States
(12) Patent Application Publication
(10) Pub. No.: US 2011/0212402 A1
(43) Pub. Date: Sep. 1, 2011

(54) PHOTOSENSITIVE RESIN COMPOSITION AND ITS APPLICATION

(76) Inventors: Meng-Yen Chou, Kaohsiung (TW); Chuan-Zong Lee, Kaohsiung (TW); Pi-Jen Cheng, Kaohsiung (TW); Jui-Kai Hu, Kaohsiung (TW)

(21) Appl. No.: 12/836,845

(22) Filed: Jul. 15, 2010

(30) Foreign Application Priority Data
Mar. 1, 2010 (TW) 099105794

(51) Int. Cl. G03F 7/20; G03F 7/004

(52) U.S. Cl. 430/286.1; 430/319

(57) ABSTRACT

A photosensitive resin composition comprising:
a photosensitive polyimide of formula (I);

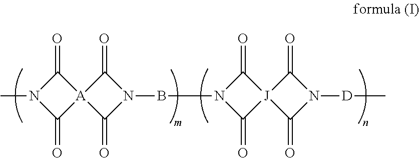

an acrylate monomer; and
a photoinitiator,
   wherein A, B, D, J, m, and n are as defined in the specification.

### RELATED APPLICATION

This application claims the benefit of Taiwan Application Serial No. 099105794, filed Mar. 1, 2010, the subject matter of which is incorporated herein by reference.

### BACKGROUND OF THE INVENTION

1. Field of the Invention

The present invention relates to a photosensitive resin composition with both good physical and chemical resistance properties. In particular, the present invention relates to a photosensitive resin composition containing polyimide, which is adapted for use as an insulation material in electronic devices, or for the formation of passivation films, surface protective films, buffer coating layers or interlayer dielectric films in semiconductor devices.

2. Descriptions of the Related Art

Over recent years, as driven by demands for lightweight, low-profile and miniaturized electronic products, various electronic components have been made increasingly smaller in size. Thus, flexible printed circuit boards (FPCBs) which feature a light weight, low profile and high-temperature resistance while allowing for mass production, have experienced rapid development. FPCBs can be found in almost all popular electronic products such as mobile phones, liquid crystal displays (LCDs), polymer light emitting diodes (PLEDs) and organic LEDs. Because of its greater flexibility compared to traditional silicon substrates and glass substrates, FPCBs are also known as flexible printed circuits (FPCs).

Typically, an FPC is provided with a coverlay film to protect the copper circuit on the FPC. An appropriate material of the coverlay film must present desirable heat resistance, dimensional stability, electrical and chemical resistance. Generally, the coverlay film is laminated onto the FPC with the following approach. The coverlay film is first processed into a specified form which has openings corresponding to the circuit of the FPC, and then an adhesive layer is formed on a side of the coverlay film and the coverlay film is attached to the FPC in alignment with the FPC. Finally, the coverlay film is hot-pressed onto the FPC. However, this approach needs to conduct processing and making openings on the very thin coverlay film, and almost all the operations for joining the coverlay film to the FPC must be accomplished manually, so it has shortcomings such as a low manufacturing yield and high cost.

As is known, the abovementioned problems may be overcome by using a photosensitive material. Photosensitive materials commonly used in the art mostly consist of epoxy resin and acrylate resin. However, the heat resistance, insulating properties, chemical resistance and mechanical strength of the coverlay films made from epoxy resin and acrylate resin are not sufficient to be used in high-end products.

Another conventional photosensitive material is the photosensitive polyimide (PSPI), which is obtained by introducing photosensitive groups into polyimide. Use of the PSPI can overcome the abovementioned problems of a low manufacturing yield and high labor cost. Moreover, polyimide has a superior thermal stability; and its satisfactory mechanical, electrical and chemical properties and the flame retardant property also meets the UL-94V0 standard. Therefore, PSPI is very suitable for use in high-end FPCs with denser and thinner lines.

Conventional PSPIs are generally made from its polyamic acid or polyamic ester precursor. For instance, Toray Industries Incorporation produces a photosensitive material by having a tertiary amine with photosensitive groups to form the ionic bonds with carboxyl (—COOH) of the polyamic acid. The manufacturing process is shown as follows:

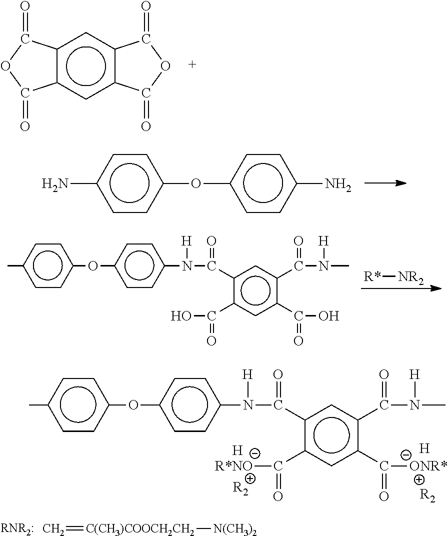

However, the photosensitive material produced in this way must be post cured at a high temperature high than 300° C. to get the desired polyimide. Unfortunately, the copper circuit on the FPC is liable to be oxidized at such a high temperature, which will unfavorably affect the electrical properties and reliabilities of the products.

To solve the problem of oxidation of the copper circuit caused by the high-temperature post-curing process, Japan laid-opened patent application No. 2003-345007 disclosed a kind of PSPI which is prepared without the high-temperature post-curing process. According to this application, a negative-type PSPI is formed by reacting acrylate monomers having tertiary amine groups with soluble polyimide having —COOH groups on its main chain. However, the acrylate monomers with tertiary amine groups, when exposed to water, tend to form alkaline substances that may lower the stability of polyimide by ring-open reaction. Furthermore, this may also lead to a shrinkage of the film during the subsequent post-curing process to cause distortion in the circuit patterns after development. Consequently, this kind of polyimide is only suitable for producing coverlay films with thicknesses less than 10 μm. In case a thicker polyimide layer of coverlay film is to be produced, use of this approach will be restricted.

### SUMMARY OF THE INVENTION

An objective of the present invention is to provide a photosensitive resin composition comprising:
a photosensitive polyimide of formula (I):

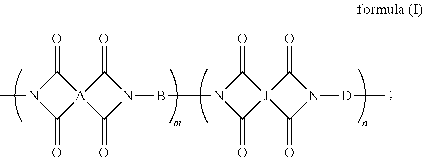

an acrylate monomer; and
a photoinitiator,
   wherein,
   A and J are independently a tetravalent organic group;
   B and D are independently a divalent organic group;
   n is 0 or an integer of greater than 0;
   m is an integer of greater than 0; and
   at least one of A and B has one or more photosensitive group(s) G* selected from a group consisting of:

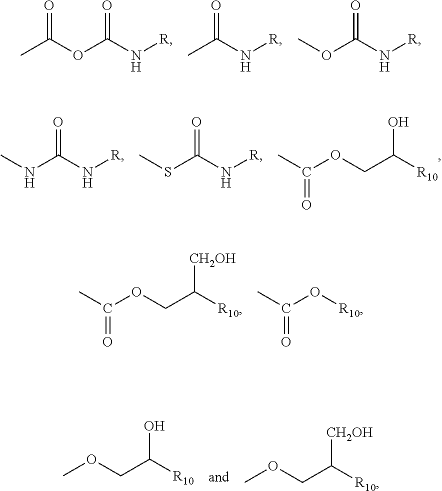

wherein,
R is an unsaturated group with —C═C— or selected from a group consisting of:

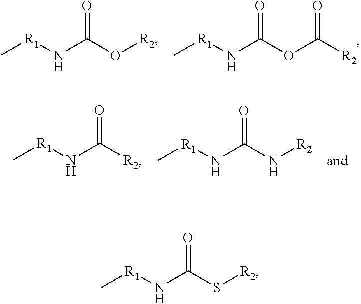

R₁ is a substituted or unsubstituted, saturated or unsaturated C₁-C₂₀ organic group, and R₂ is an unsaturated group with —C═C—; and
R₁₀ is an unsaturated group with an acrylate group.

Another objective of the present invention is to provide a method for forming a polyimide circuit, comprising:
applying the abovementioned composition onto a substrate;
performing an exposure step on the substrate;
performing a development step on the substrate; and
thermally treating the substrate at a temperature ranging from about 100° C. to about 200° C.

The photosensitive resin composition of the present invention requires a lower post-curing temperature when used to produce a coverlay film of an FPC, which represents savings in energy. Furthermore, because the photosensitive resin composition of the present invention can be used to produce coverlay films that are greater than 25 μm in thickness, the industrial demands for this are fully satisfied.

The detailed technology and preferred embodiments implemented for the subject invention are described in the following paragraphs accompanying the appended drawings for people skilled in this field to well appreciate the features of the claimed invention.

### DESCRIPTION OF THE PREFERRED EMBODIMENT

Hereinafter, some embodiments of the present invention will be described in detail in conjunction with the attached drawings. However, the present invention may also be practiced in various different forms without departing from the spirits of the present invention. The scope of the present invention shall not be considered to be limited to what is illustrated herein.

The photosensitive resin composition of the present invention comprises:
a photosensitive polyimide of formula (I):

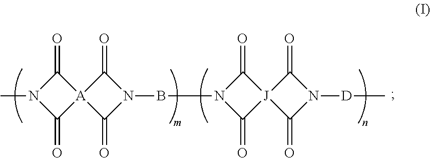

an acrylate monomer; and
a photoinitiator,
   wherein,
   A and J are independently a tetravalent organic group;
   B and D are independently a divalent organic group;
   n is 0 or an integer of greater than 0;
   m is an integer of greater than 0; and
   at least one of A and B has one or more photosensitive group(s) G* selected from a group consisting of:

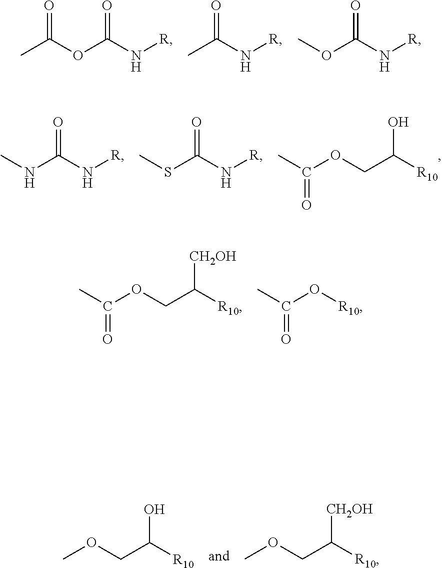

wherein,
R is an unsaturated group with —C═C— or selected from a group consisting of:

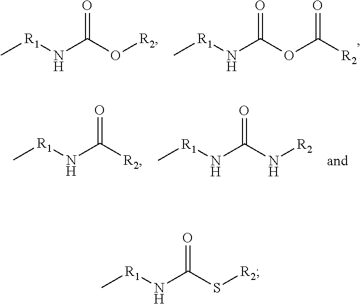

and R₁₀ is an unsaturated group with an acrylate group;
wherein, R₁ is a substituted or unsubstituted, saturated or unsaturated C₁-C₂₀ organic group, and R₂ is an unsaturated group with —C═C—.

The above-mentioned unsaturated group with —C═C— is preferably selected from a group consisting of:

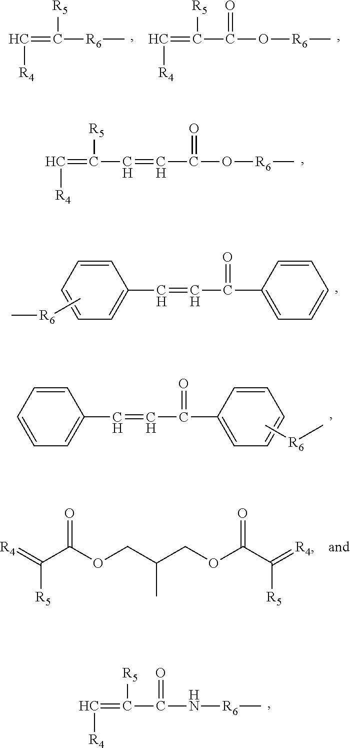

wherein,
R₄ and R₅ are independently H, or a substituted or unsubstituted C₁-C₇ organic group; and
R₆ is a covalent bond, —O—, or a substituted or unsubstituted C₁-C₂₀ organic group.

More preferably, the unsaturated group with —C═C— is selected from a group consisting of:

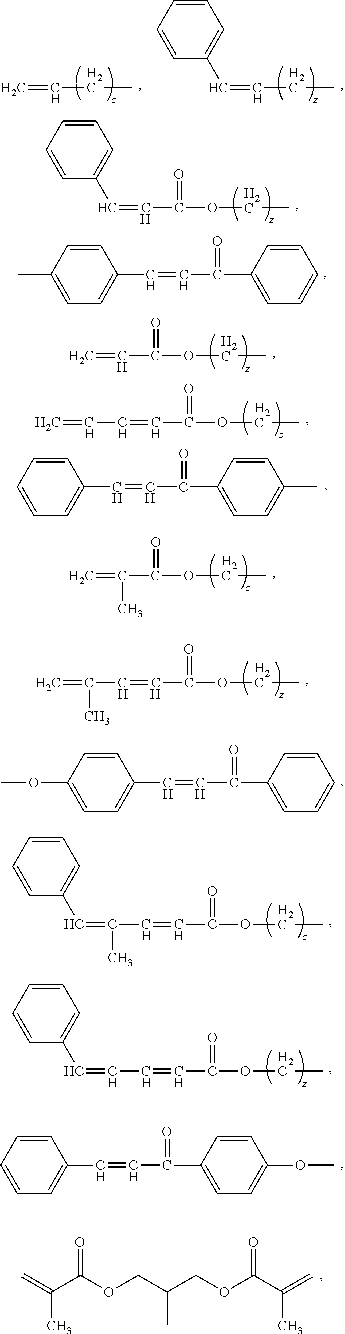

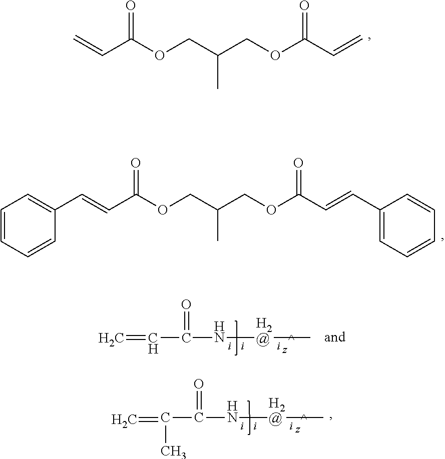

wherein, z is an integer ranging from 0 to 6.

Most preferably, the above-mentioned unsaturated group with —C═C— is selected from a group consisting of:

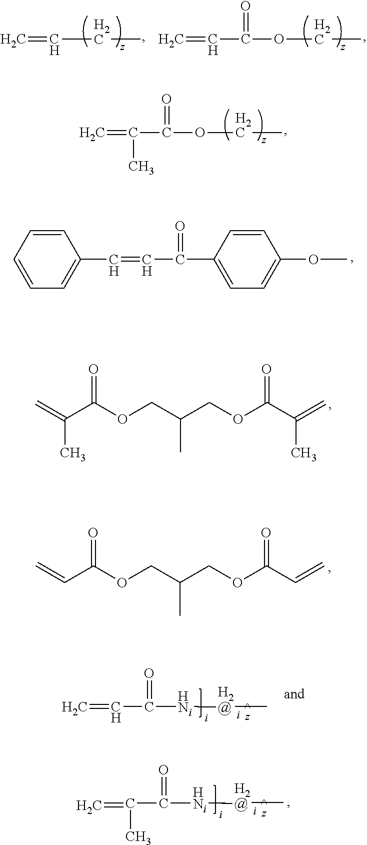

wherein, z is an integer ranging from 0 to 6.
R₁ is a substituted or unsubstituted, saturated or unsaturated C₁-C₂₀ organic group, which may be selected from a group consisting of:

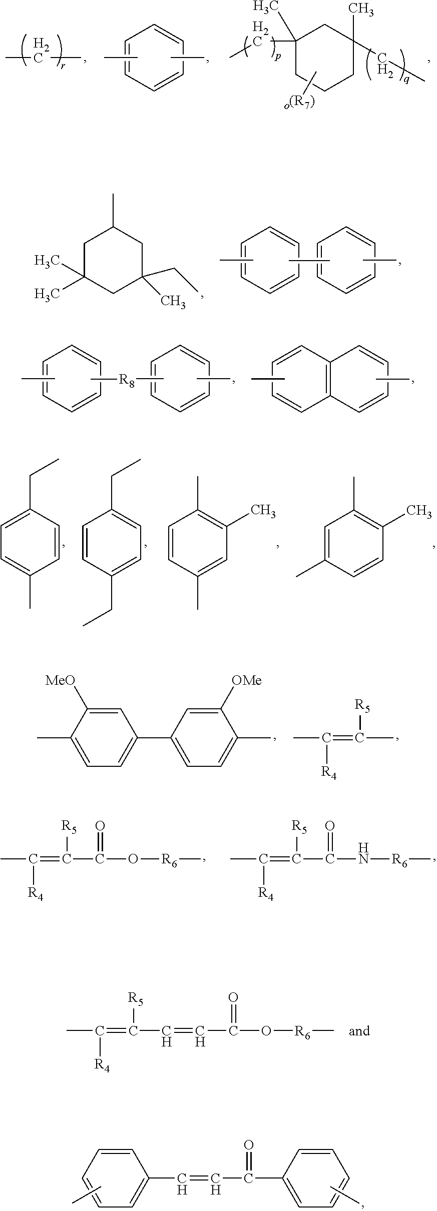

wherein,
r is an integer of greater than 0, and preferably an integer ranging from 1 to 20;
o, p and q are independently 0 or an integer of greater than 0, and preferably an integer ranging from 0 to 10;
R₄, R₅ and R₆ have the meanings defined hereinabove;
R₇ is H or a substituted or unsubstituted C₁-C₁₂ organic group; and
R₈ is a covalent bond or selected from a group consisting of:

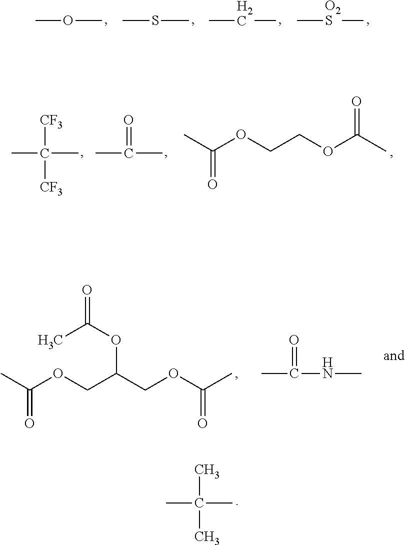

Preferably, R₁ is selected from a group consisting of:

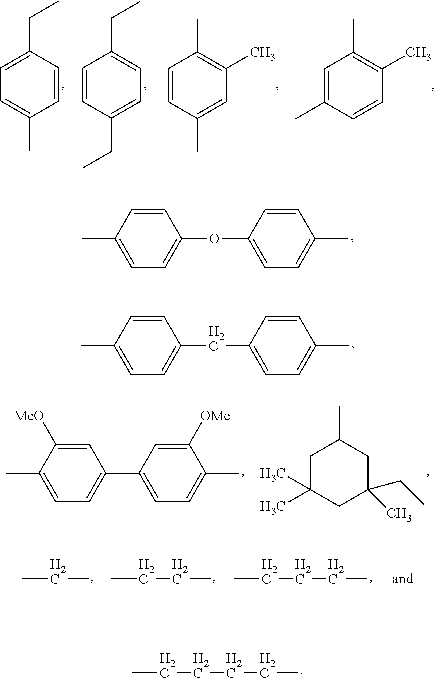

R₁₀ is an unsaturated group with an acrylate group. In the present invention, the unsaturated group with an acrylate group is

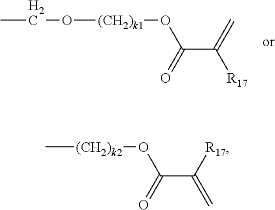

wherein R₁₇ is H or methyl, and K1 and K2 are independently an integer ranging from 0 to 6, and preferably ranging from 2 to 4.

Additionally, as will be appreciated by those of ordinary skill in the art, when n in formula (I) is not zero, the polymerization units with photosensitive groups may be arranged together or be arranged to randomly interlace with the polymerization units without photosensitive groups.

In the PSPI of formula (1) for use in the photosensitive resin composition of the present invention, A in formula (1) may be selected from a group consisting of:

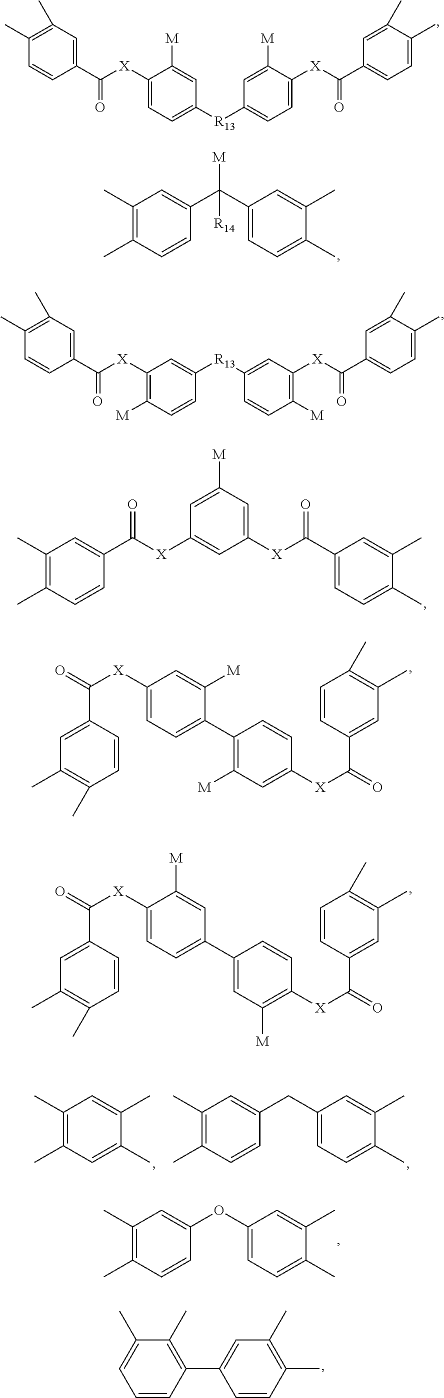

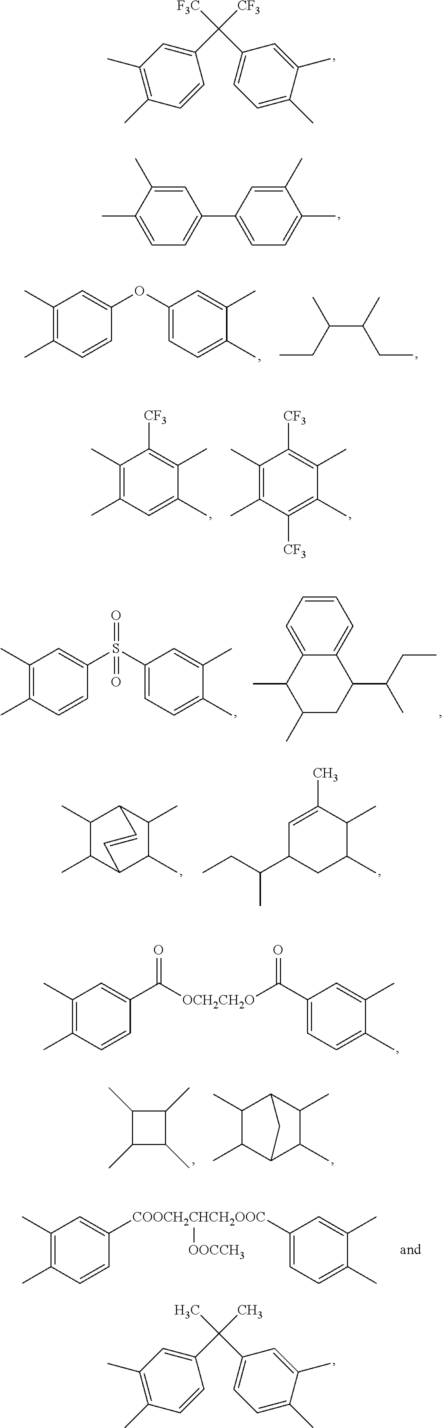

wherein,
M is photosensitive group G*, H, COOH, OH, NH₂ or SH, and G* has the meanings defined hereinabove;

### R₁₃ is —CH₂—, —O—, —S—, —CO—, —SO₂—, —C(CH₃)₂— or —C(CF₃)₂—;

### R₁₄ is —H or —CH₃; and

### X is —O—, —NH— or —S—.

Preferably, A in formula (1) is selected from a group consisting of:

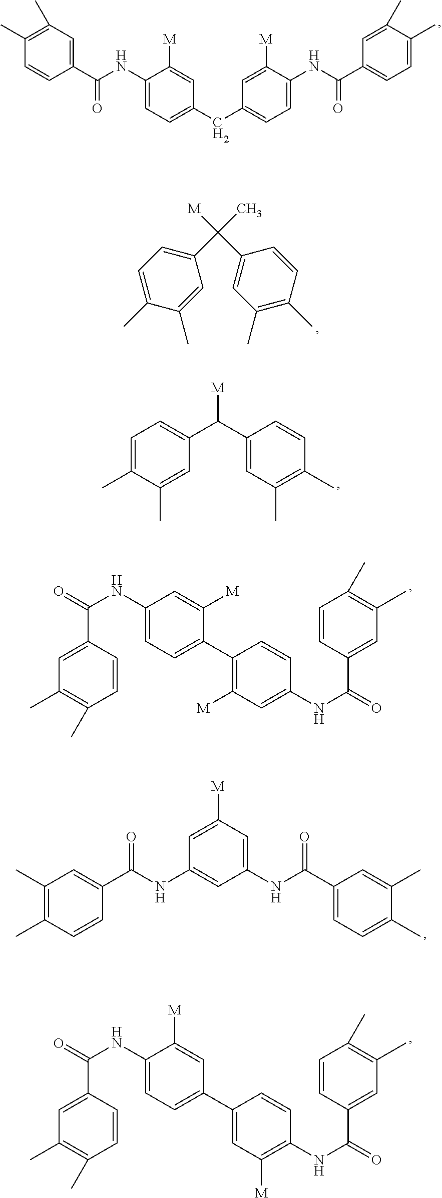

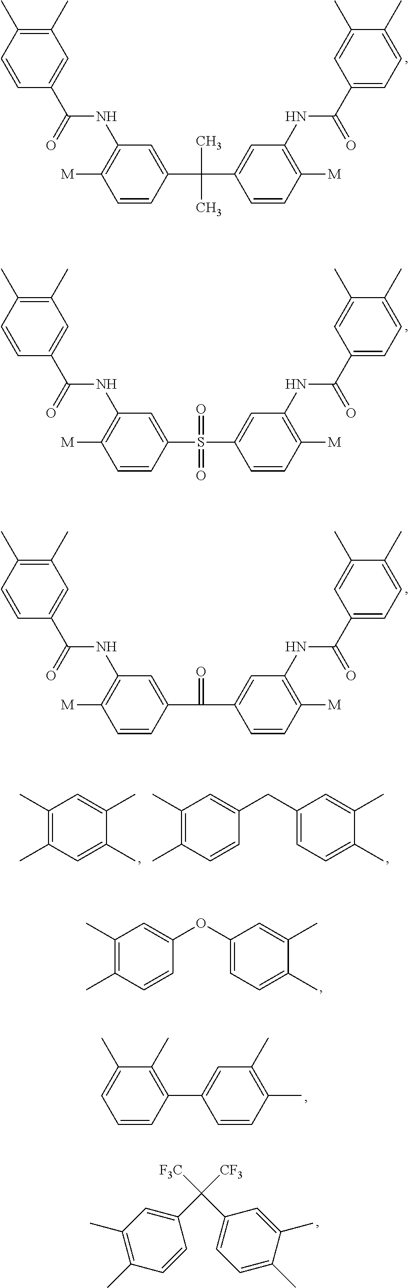

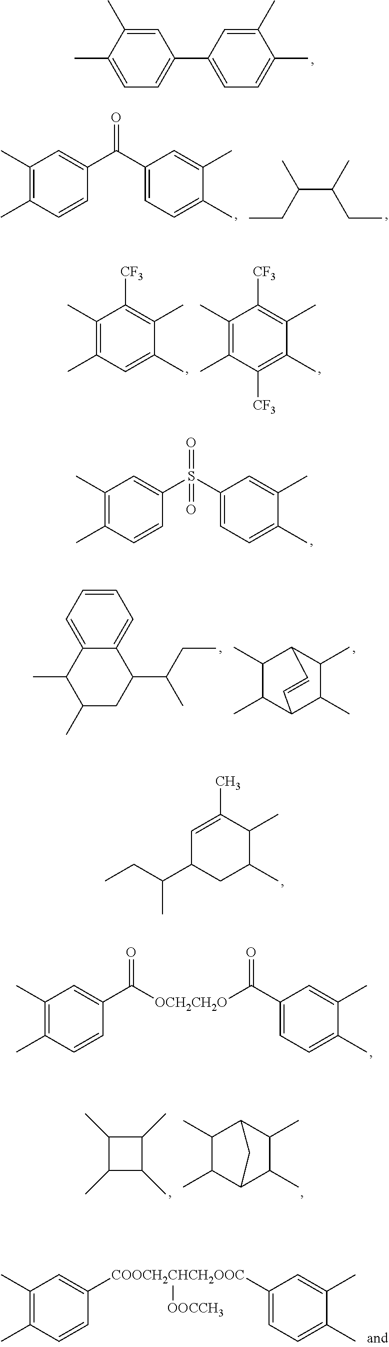

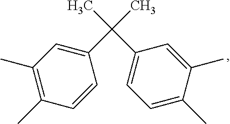

wherein, M is as defined hereinabove.

In the PSPI of formula (1) for use in the photosensitive resin composition of the present invention, J in formula (1) is an acid anhydride residue resulting from the polymerization reaction, and may be selected from a group consisting of:

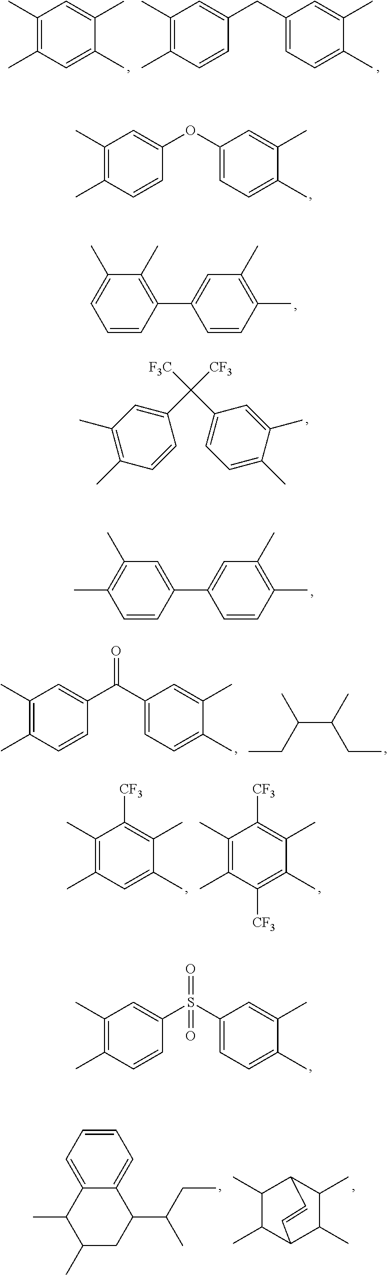

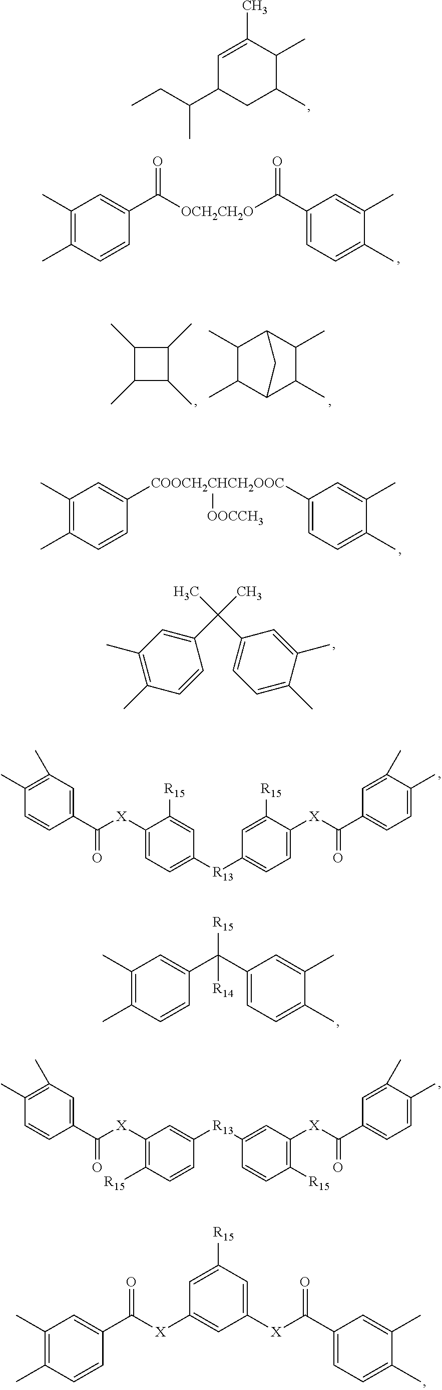

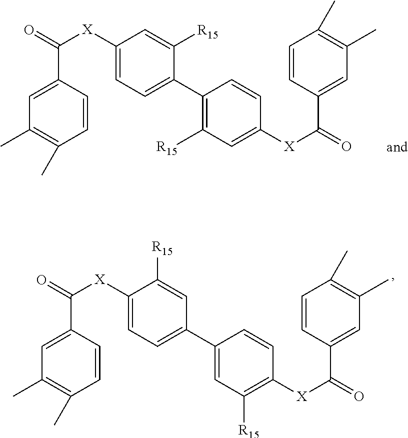

wherein,
R₁₃, R₁₄ and X have the meanings defined hereinabove; and

### R₁₅ is —H, —OH, —COOH, —NH₂ or —SH.

Preferably, J is selected from a group consisting of:

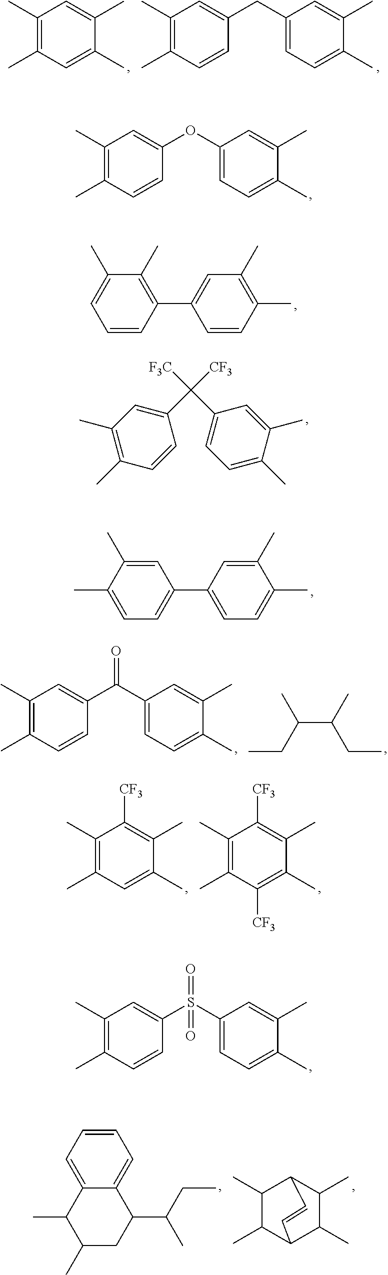

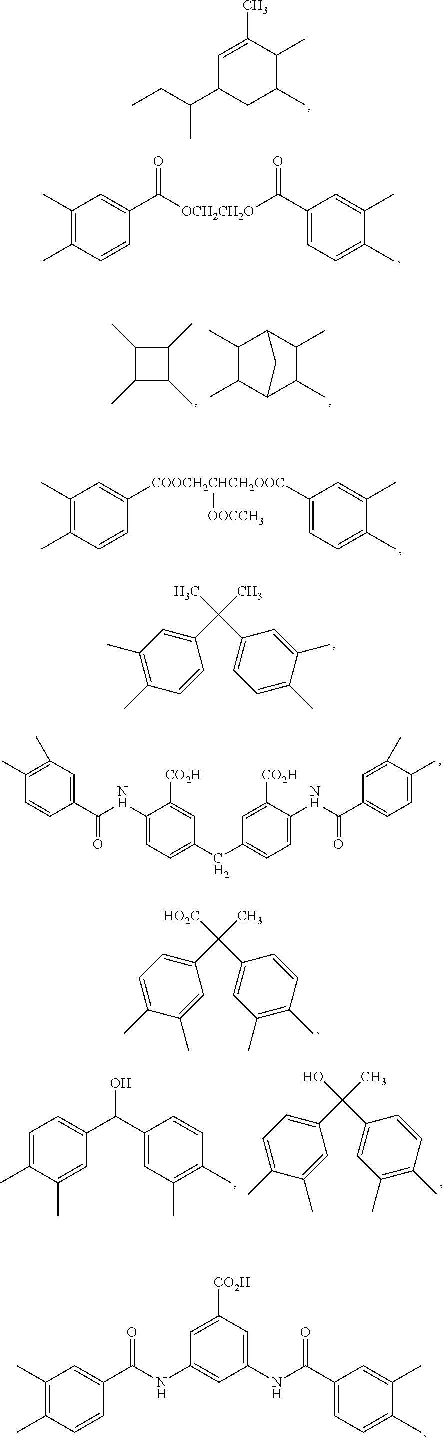

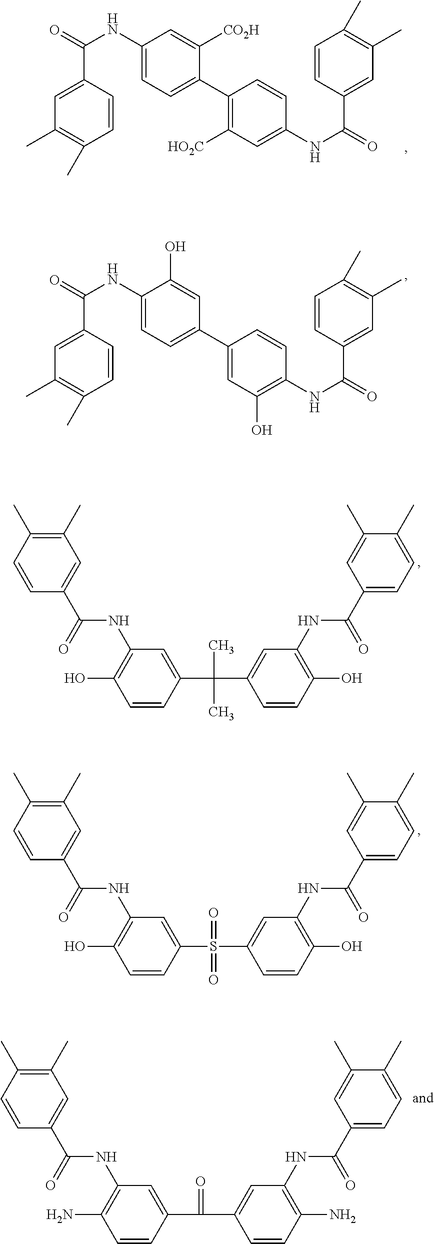

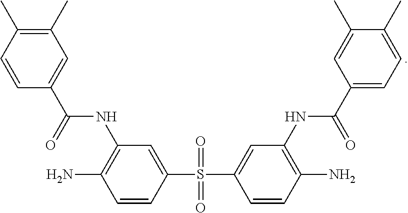

In the PSPI of formula (1) for use in the photosensitive resin composition of the present invention, B in formula (1) may be selected from a group consisting of:

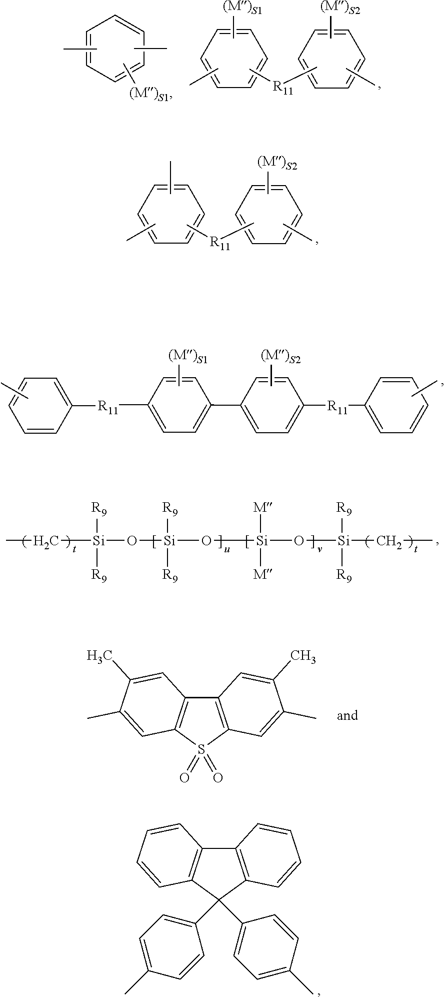

wherein,
M″ is H, C₁-C₄ alkyl, C₁-C₄ perfluoroalkyl, methoxy, ethoxy, halogen, OH, COOH, NH₂, SH or photosensitive group G*, wherein G* has the meanings defined hereinabove;
S1 and S2 are independently an integer ranging from 1 to 4;
t is an integer of greater than 0, and preferably an integer ranging from 1 to 6;
u is 0 or an integer of greater than 0, and preferably an integer ranging from 1 to 12;
v is 0 or an integer of greater than 0, and preferably an integer ranging from 1 to 12;
R₉ is H, methyl, ethyl or phenyl; and
R₁₁ is a covalent bond or selected from a group consisting of:

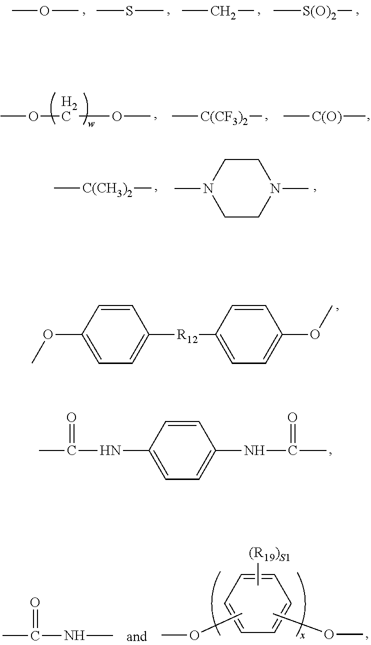

wherein, w and x are independently an integer of greater than 0, and preferably, w is an integer ranging from 1 to 12 and x is an integer ranging from 1 to 4, and S1 has the meanings defined hereinabove,
R₁₂ is a covalent bond, —SO₂—, —C(O)—, —C(CF₃)₂—, or a substituted or unsubstituted C₁-C₁₈ organic group, and R₁₉ is H or C₁-C₄ alkyl.

Preferably, B in formula (1) is selected from a group consisting of:

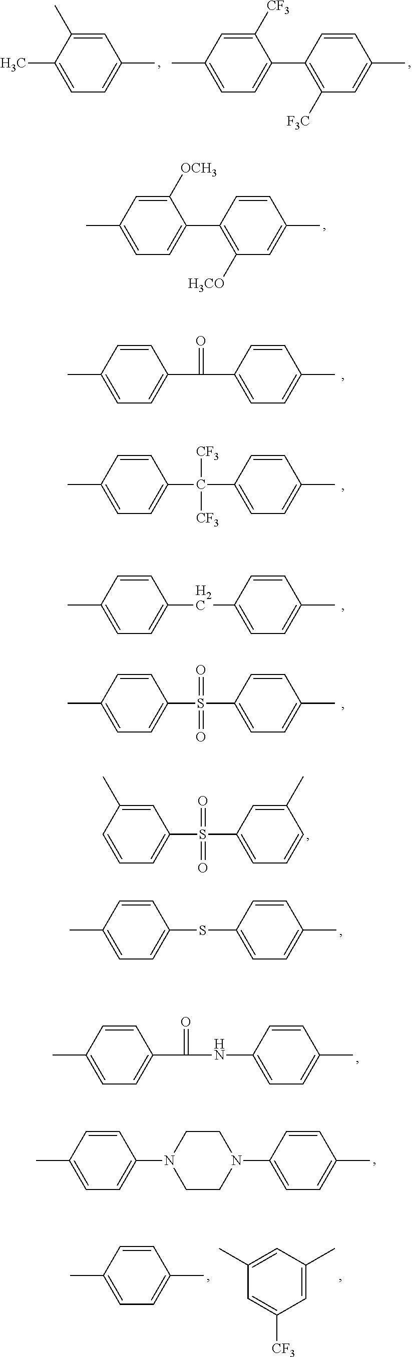

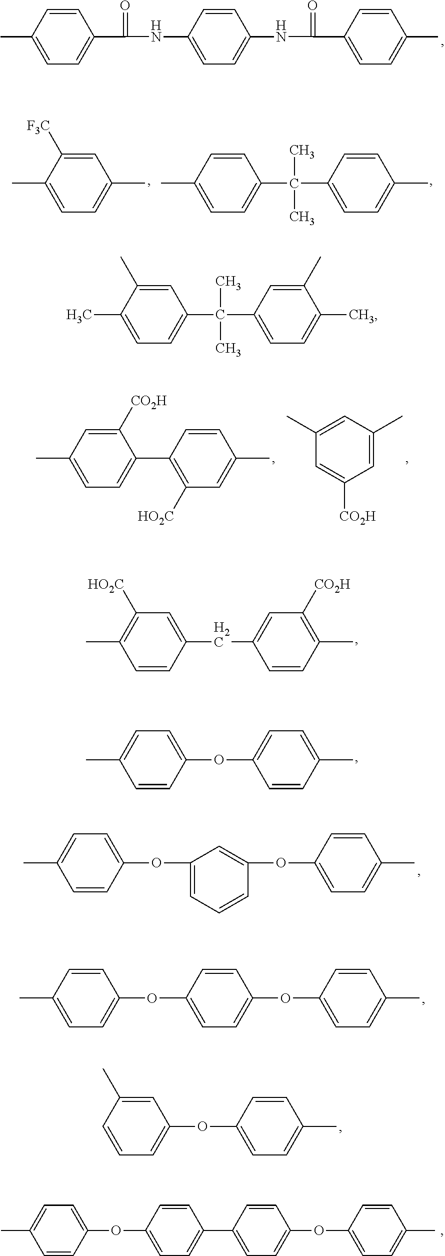

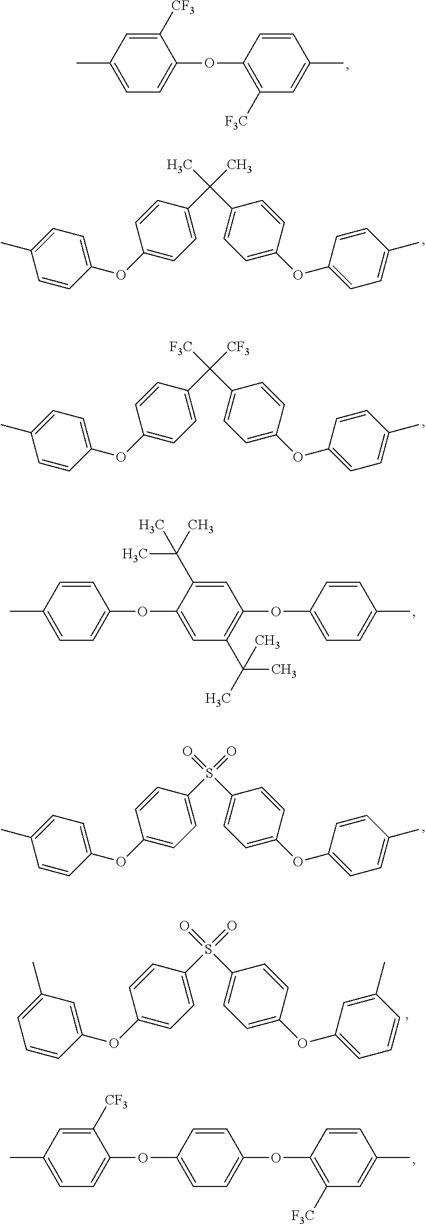

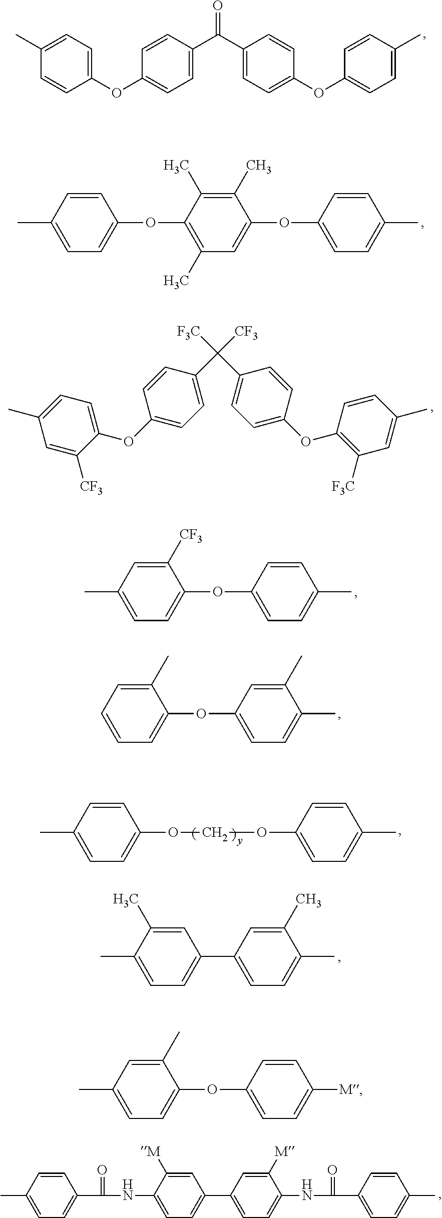

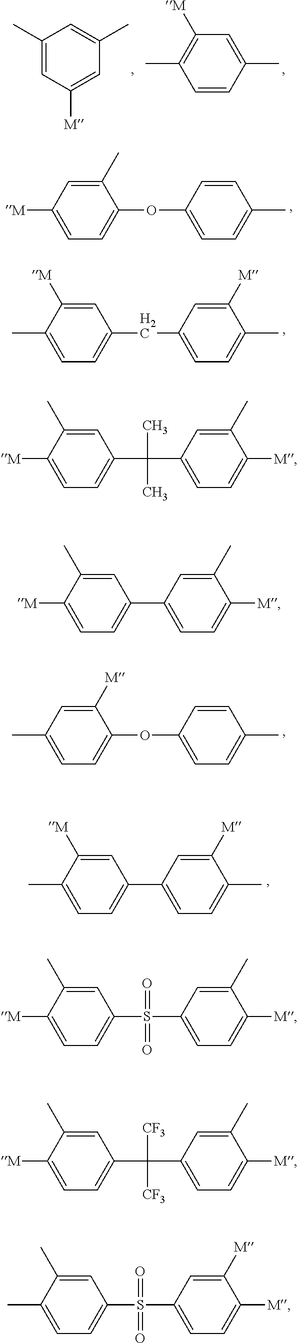

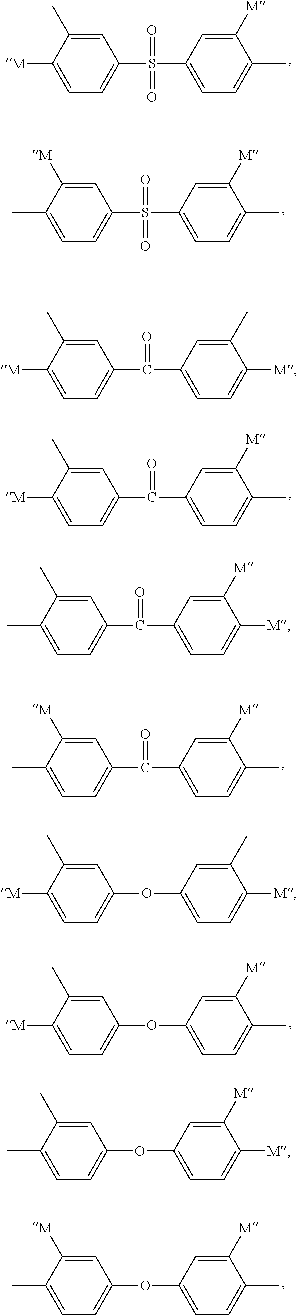

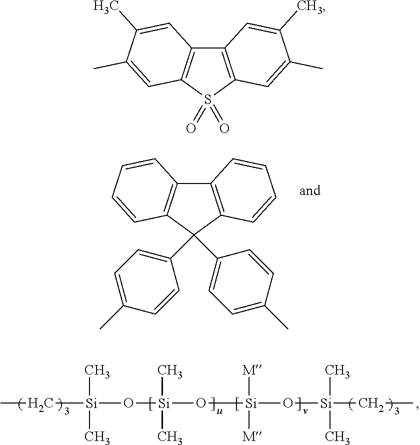

wherein, M″, u and v are as defined hereinabove, and y is an integer ranging from 1 to 12, and preferably from 1 to 6.

In the PSPI of formula (1) for use in the photosensitive resin composition of the present invention, there is no particular limitation on D in formula (1), which may be a bivalent aromatic group, a bivalent aliphatic group or a bivalent group with siloxy group. Preferably, D is selected from a group consisting of:

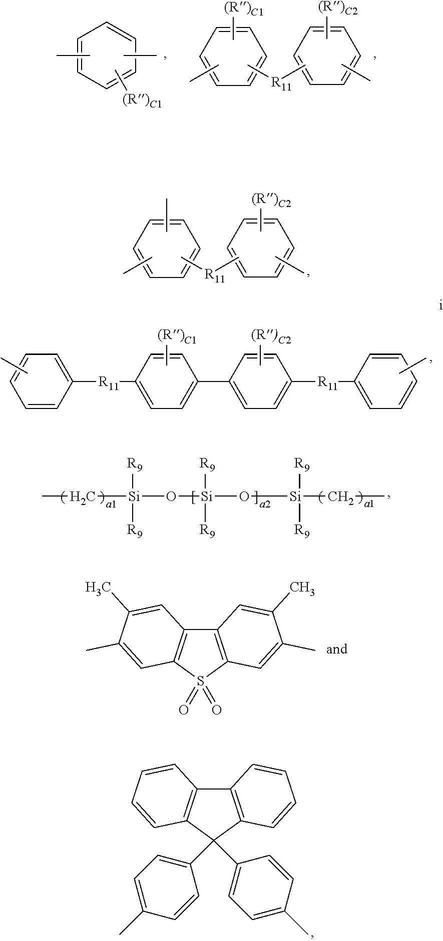

wherein,
R″ is H, C₁-C₄ alkyl, C₁-C₄ perfluoroalkyl, methoxy, ethoxy, halogen, OH, COOH, NH₂, or SH;
C1 and C2 are independently an integer ranging from 1 to 4;
a1 and a2 are independently an integer of greater than 0, and preferably, a1 is an integer ranging from 1 to 6 and a2 is an integer ranging from 5 to 15; and
R₉ and R₁₁ have the meanings defined hereinabove.

More preferably, D in formula (I) is selected from a group consisting of:

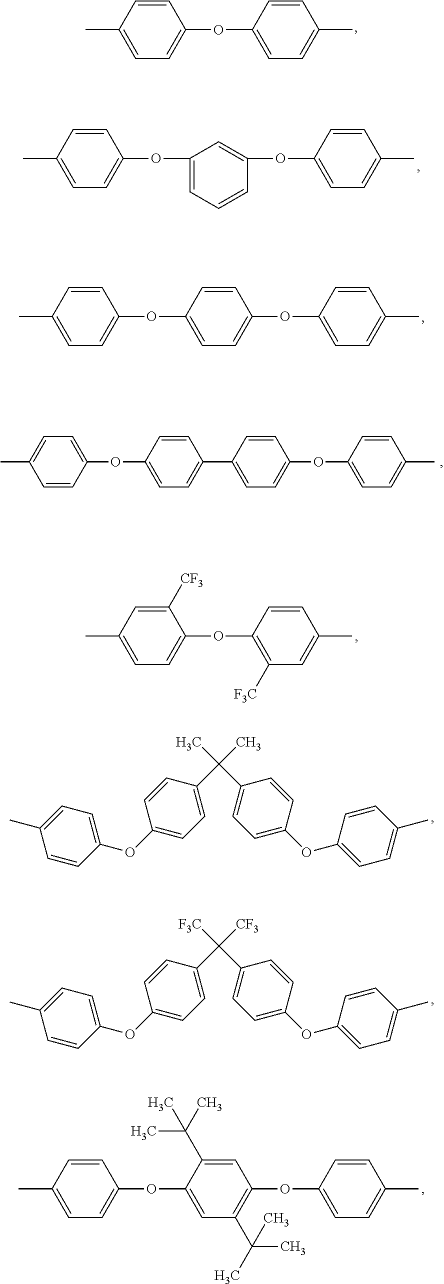

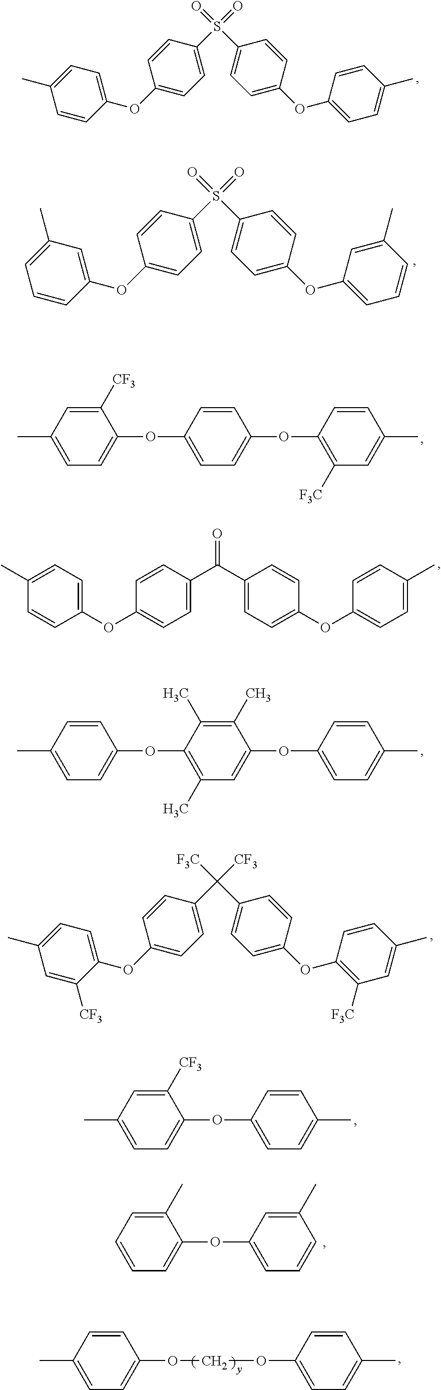

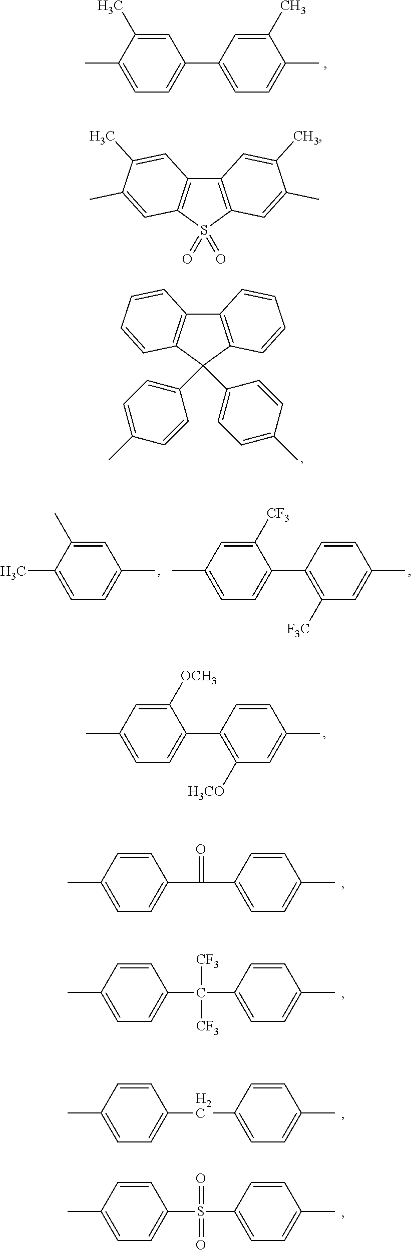

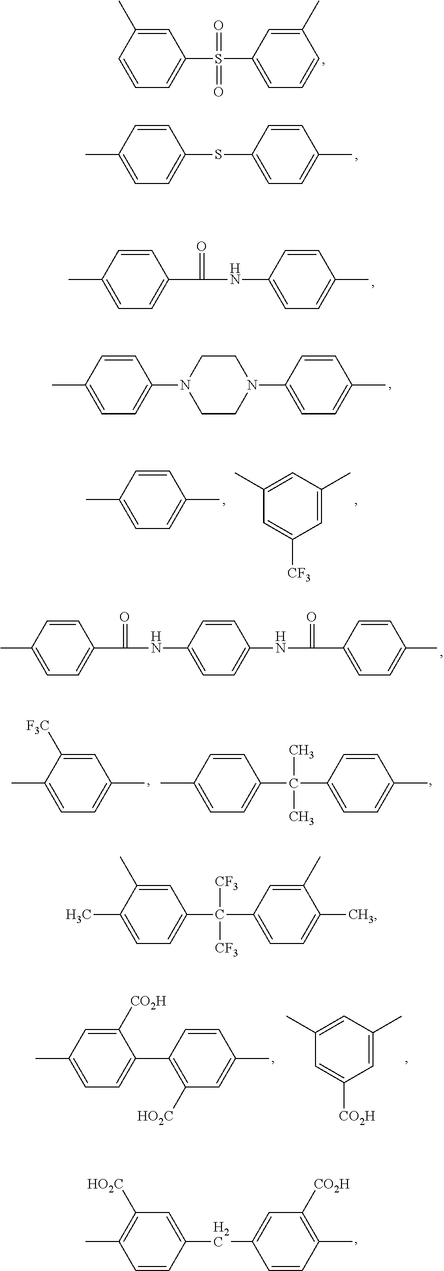

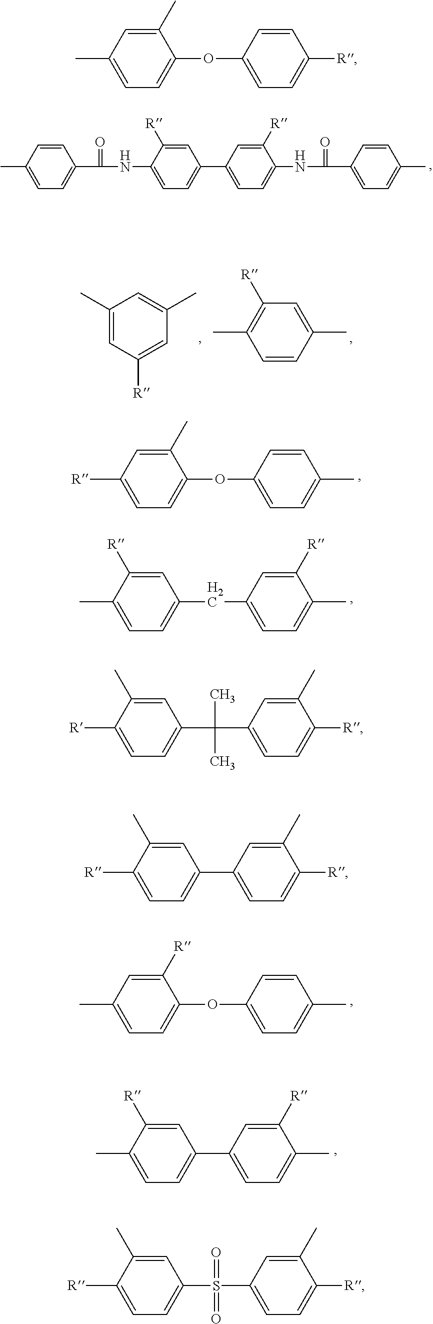

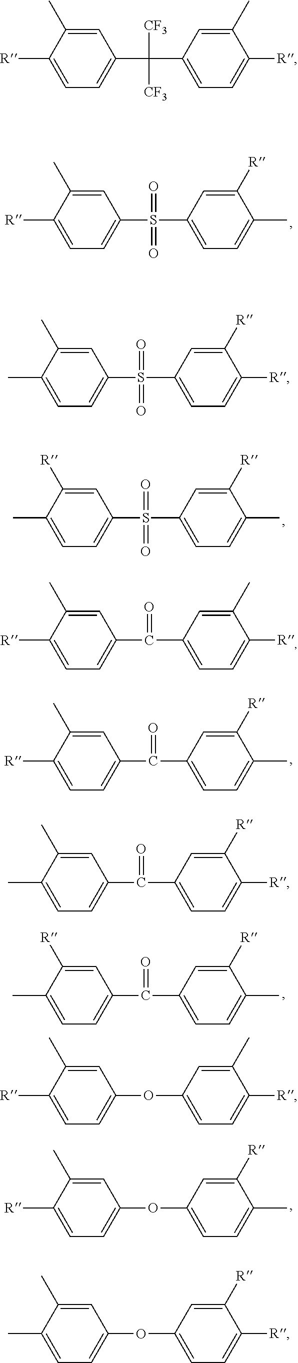

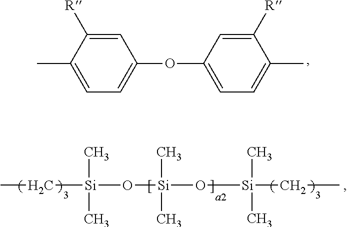

wherein, y is an integer ranging from 1 to 12, and preferably from 1 to 6, and R″ and a2 have the meanings defined hereinabove.

The PSPI of the photosensitive resin composition of the present invention may be prepared by any suitable conventional processes. Generally, diamine monomers are polymerized with acid anhydride monomers containing reactive functional groups (e.g., OH, COOH, NH₂ or SH), or acid anhydride monomers are polymerized with diamine monomers containing reactive functional groups to result in polyimide with reactive functional groups. Then, an epoxy acrylate compound or an isocyanate compound with a photosensitive group is added to the resulting product to modify the resulting polyimide into photosensitive polyimide with a photosensitive group at its side chain.

The isocyanate compound used for modifying polyimide in the present invention has the following structure: O═C═N—R*, wherein R* is a photosensitive group with a —C═C— unsaturated group or is a group with the following structure:

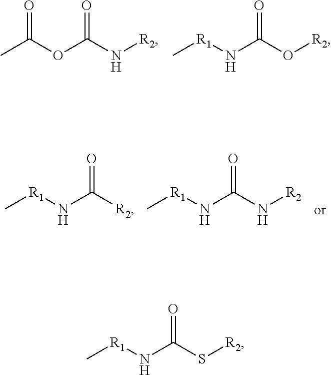

wherein, R₂ is an photosensitive group with a —C═C— unsaturated group, and R₁ has the meanings defined hereinabove.

The epoxy acrylate compound used for modifying polyimide in the present invention has the following structure:

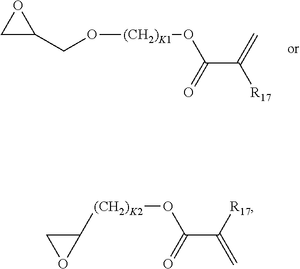

wherein K1, K2 and R₁₇ have the meanings defined hereinabove.

For example, the PSPI of the present invention may be prepared through one of the following four processes.

(I) Diamine monomers are polymerized with acid anhydride monomers containing reactive functional groups and an epoxy acrylate compound is added for modification. The reaction scheme is described briefly as follows:

(a) Polymerization reaction:

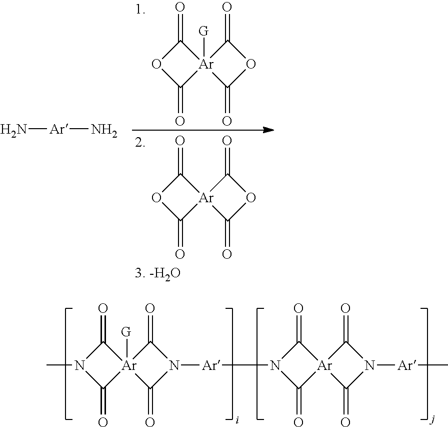

wherein, G is a reactive functional group, Ar is a tetravalent organic group, Ar′ is a divalent organic group, i is an integer of greater than 0, and j is 0 or an integer of greater than 0.

(b) Modifying: If G is COOH, for example, an epoxy acrylate compound (e.g., glycidyl methacrylate) is added to the product from step (a) to undergo ring-opening reaction with COOH, resulting in a polyimide with a photosensitive group at its side chain.

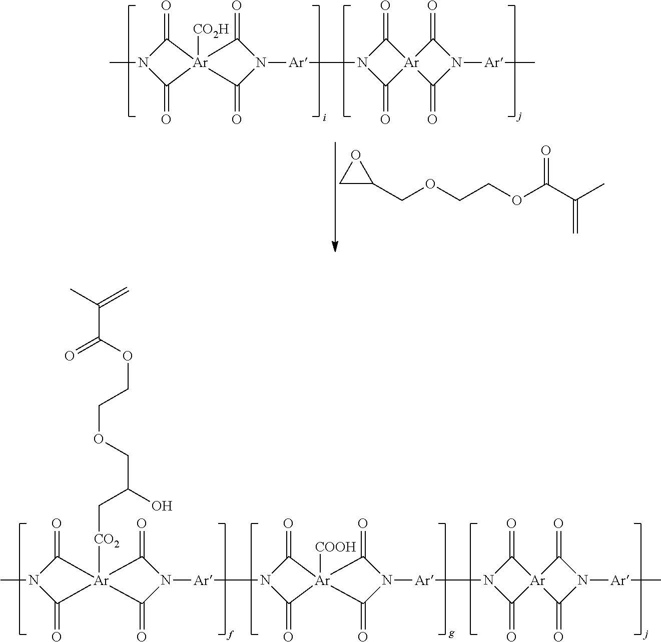

wherein, f+g=i.

(II) Diamine monomers are polymerized with acid anhydride monomers containing reactive functional groups and an isocyanate compound is added for modification. The reaction scheme is described briefly as follows:

(a) Polymerization reaction:

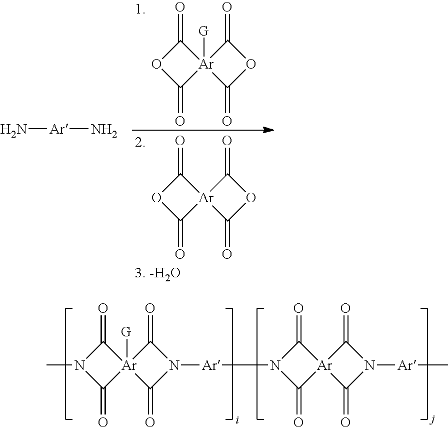

wherein, G, Ar, Ar′, i and j have the meanings defined hereinabove.

(b) Modifying: If G is COOH, for example, an isocyanate compound of formula O═C═N—R is added to the product from step (a) to react with COOH, resulting in a polyimide with a photosensitive group at its side chain.

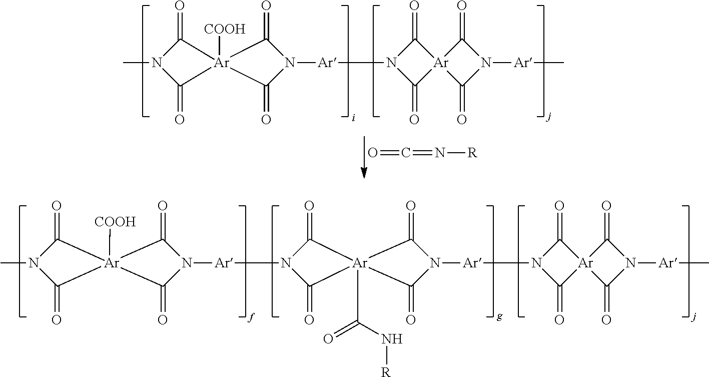

wherein, f+g=i.

(III) Acid anhydride monomers are polymerized with diamine monomers containing reactive functional groups and an isocyanate compound is added for modification. The reaction process is described briefly as follows:

(a) Polymerization reaction:

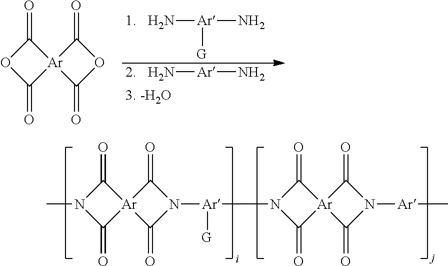

wherein, G, Ar, Ar′, i and j have the meanings defined hereinabove.

(b) Modifying: If G is COOH, for example, an isocyanate compound of formula O═C═N—R is added to the product from step (a) to react with COOH, resulting in a polyimide with a photosensitive group at its side chain.

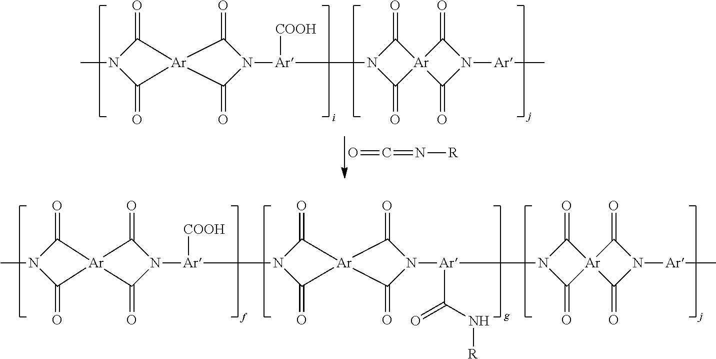

wherein, f+g=i.

(IV) Acid anhydride monomers are polymerized with diamine monomers containing reactive functional groups and an epoxy acrylate compound is added for modification. The reaction scheme is described briefly as follows:

(a) Polymerization reaction:

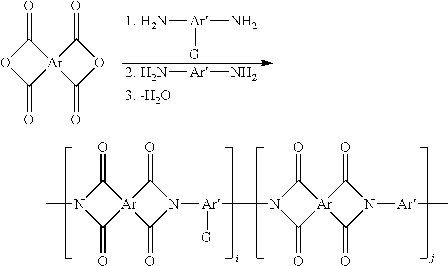

wherein, G, Ar, Ar′, i and j have the meanings defined hereinabove.

(b) Modifying: If G is COOH, for example, an epoxy acrylate compound (e.g., glycidyl methacrylate) is added to the product from step (a) to undergo a ring-opening reaction with COOH, resulting in a polyimide with a photosensitive group at its side chain.

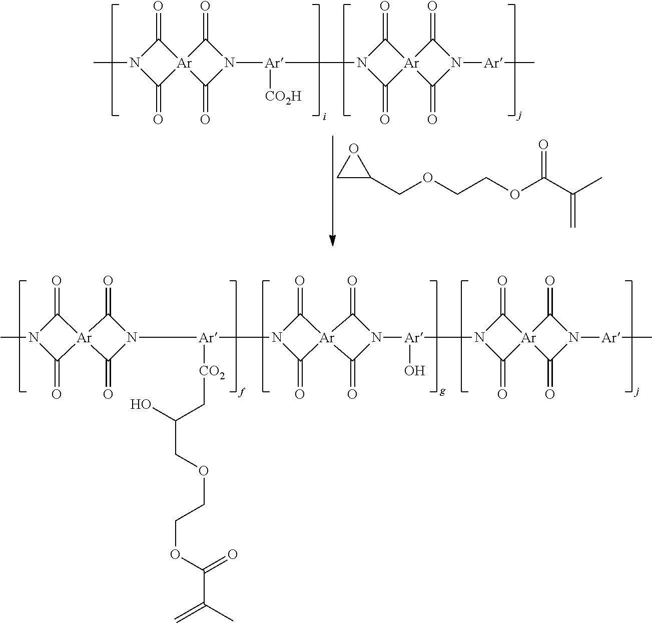

wherein, f+g=i.

In addition to the processes illustrated above, a photosensitive polyimide may also be obtained by polymerizing diamine monomers and acid anhydride monomers with each other, both with reactive functional groups, and then modifying the polymerization product with an epoxy acrylate compound or an isocyanate compound according to such as step (b) of the processes (I) to (IV). The photosensitive polyimide thus prepared has photosensitive groups at both of its acid anhydride and diamine residues.

In the photosensitive resin composition of the present invention, if the PSPI has too few photosensitive groups, the crosslink density would become very low during the photopolymerization process to lower the photosensitivity of the resulting composition, thereby causing distortion of the circuits after being exposed and developed. On the contrary, if the PSPI has too many photosensitive groups, the content of hydroxyls or carboxyls would become very deficient in the resulting polymer to lower the solubility of the polymer in an alkaline development solution, thereby leading to residues of the unexposed portions after the development. Therefore, to further control the content of photosensitive groups in the polyimide, the ratio of m (number of portions with photosensitive groups) to n (number of portions without photosensitive groups) in formula (I) is preferably about 0.04 to about 25, and more preferably about 0.1 to about 10.

Acrylate monomers for use in the photosensitive resin composition of the present invention are acrylate monomers with at least one —C═C—, and preferably multi-functional acrylate monomers with two or more —C═C—. Through the addition of such monomers, crosslinking can be formed among molecules, which is favorable for the improvement of the utility of the composition.

In the photosensitive resin composition of the present invention, the amount of acrylate monomers is about 5 parts by weight to about 80 parts by weight based on 100 parts by weight of the photosensitive polyimide, and preferably about 10 parts by weight to about 40 parts by weight. If the acrylate monomers are added in a too small amount, the crosslink density is too low, and this will lead to film shrinkage after the post-curing process, resulting in defects such as circuit deformation or a lower manufacturing yield. On the contrary, if the acrylate monomers are added in a too large amount, the overall physical properties of the resulting composition will become poor (e.g., the flame retardant property, electrical property and chemical property would be degraded), making it unsuitable for use as an excellent coverlay film.

The acrylate monomer suitable for use in the present invention may be selected from a group consisting of ethyleneglycol dimethacrylate, ethyleneglycol diacrylate, bisphenol A EO-modified diacrylate, bisphenol A EO-modified dimethacrylate, bisphenol F EO-modified diacrylate, bisphenol F EO-modified dimethacrylate, propyleneglycol dimethacrylate, trimethylolpropane triacrylate, trimethylolpropane trimethacrylate, pentaerythritol triacrylate, pentaerythritol trimethacrylate, 1,6-hexanediol diacrylate, neopentyl glycol diacrylate, pentaerythritol diacrylate, pentaerythritol triacrylate, pentaerythritol tetraacrylate, dipentaerythritol hexacrylate, tetramethylolpropane tetraacrylate, tetraethylene glycol diacrylate, 1,6-hexanediol dimethacrylate, neopentanediol dimethacrylate, pentaerythritol dimethacrylate, dipentaerythritol hexmethacrylate, tetramethylolpropane tetramethacrylate, tetraethylene glycol dimethacrylate, diethylene glycol dimethacrylate, triethylene glycol dimethacrylate, poly(ethylene glycol) dimethacrylate, 1,3-butanediol dimethacrylate, poly(ethylene glycol) diacrylate, tripropylene glycol diacrylate, poly(propylene glycol diacrylate), tetramethylolmethane triacrylate, tetramethylolmethane tetraacrylate, poly(propylene glycol) dimethacrylate, 1,4-butanediol diacrylate, 3-methyl-1,5-pentanediol dimethacrylate, 1,9-nonanediol acrylate, 2,4-diethyl-1,5 pentanediol dimethacrylate, 1,4-cyclohexane dimethanol dimethacrylate, dipropyleneglycol diacrylate, tricyclododecane dimethanol diacrylate, 2,4-diethyl-1,5 pentanediol diacrylate, trimethylol propane ethoxylate triacrylate (3EOTMPTA), trimethylolpropane propoxylate triacrylate, isocyanurate triacrylate, isocyanurate diacrylate, isocyanurate tri(ethane acrylate), pentaerythritol tetraacrylate (PETEA), ethoxylated pentaerythritol tetraacrylate, propoxylated pentaerythritol tetraacrylate, di-trimethylolpropane tetraacrylate, and combinations thereof, but is not limited thereto.

Preferably, the present invention uses the acrylate monomer selected from a group consisting of ethyleneglycol dimethacrylate, ethyleneglycol diacrylate, bisphenol A EO-modified diacrylate, bisphenol A EO-modified dimethacrylate, bisphenol F EO-modified diacrylate, bisphenol F EO-modified dimethacrylate, propyleneglycol dimethacrylate, tripropylene glycol diacrylate, trimethylol propane ethoxylate triacrylate, dipentaerythritol hexacrylate, trimethylolpropane triacrylate, trimethylolpropane trimethacrylate, pentaerythritol triacrylate, pentaerythritol trimethacrylate, and combinations thereof.

In addition to the aforementioned photosensitive polyimide and acrylate monomers, the photosensitive resin composition of the present invention further comprises a photoinitiator. The photoinitiator is adapted to generate free radicals when exposed to light illumination to initiate a polymerization reaction through the transfer of free radicals. There is no particular limitation on the photoinitiators that can be used in the photosensitive resin composition of the present invention. Preferably, the used photoinitiator comprises a compound which can absorb a light with a wavelength ranging from about 350 nm to about 500 nm to generate free radicals.

In the photosensitive resin composition of the present invention, the species and amount of the photoinitiator usually depend on the specie of the acrylate monomers used. Generally, based on 100 parts by weight of the photosensitive polyimide, the amount of the photoinitiator is about 0.01 parts by weight to about 20 parts by weight, and preferably about 0.05 parts by weight to about 5 parts by weight. If the photoinitiator is added in a too small amount, the photosensitivity will be reduced due to an insufficient amount of free radicals during the exposure. On the contrary, if the photoinitiator is added in a too large amount, the exposure light will be overly absorbed by the coating film surface. Then, it is difficult for the exposure light to reach inside, thereby leading to a non-uniform polymerization rate between the inside and the outside.

The photoinitiator suitable for use in the present invention may be, for example, selected from a group consisting of: benzophenone, 2,4,6-trimethylbenzoyl diphenyl phosphine oxide, bis-4,4′-diethylaminobenzophenone, camphorquinone, 3,5-bis(diethylaminobenzylidene)-N-methyl-4-piperidone, 3,5-bis(dimethylaminobenzylidene)-N-methyl-4-piperidone, 3,5-bis(diethylaminobenzylidene)-N-ethyl-4-piperidone, 3,3′-carbonyl-bis(7-diethylamino)cumarin, 3,3′-carbonyl-bis(7-dimethylamino)cumarin, riboflavin tetrabutyrate, 2-methyl-1-[4-(methylthio)phenyl]-2-morpholinopropan-1-one, 2,4-dimethylthioxanthone, 2,4-diethylthioxanthone, 2,4-diisopropylthioxanthone, 3,5-dimethylthioxanthone, 3,5-diisopropylthioxanthone, 1-phenyl-2-(ethoxycarbonyl)oxyiminopropan-1-one, benzoin ether, bezoin isopropyl ether, benzanthrone, 5-nitroacenaphthene, 2-nitrofluorene, anthrone, 1,2-benzanthraquinone, 1-phenyl-5-mercapto-1H-tetrazole, thioxanthen-9-one, 10-thioxanthenone, 3-acetylindole, 2,6-di(p-dimethylaminobenzal)-4-carboxycyclohexanone, 2,6-di (p-dimethylaminobenzal)-4-hydroxycyclohexanone, 2,6-di(p-diethylaminobenzal)-4-carboxcyclohexanone, 2,6-di(p-diethylaminobenzal))-4-hydroxycyclohexanone, 4,6-dimethyl-7-ethylaminocumarin, 7-diethylamino-4-methylcumarin, 7-diethylamino-3-(1-methylbenzoimidazolyl)cumarin, 3-(2-benzoimidazolyl)-7-diethylaminocumarin, 3-(2-benzothiazolyl)-7-diethylaminocumarin, 2-(p-dimethylaminostyryl)benzooxazole, 2-(p-dimethylaminostyryl)quinoline, 4-(p-dimethylaminostyryl)quinoline, 2-(p-dimethylaminostyryl)benzothiazole, 2-(p-dimethylaminostyryl)-3,3-dimethyl-3H-indole, and combinations thereof. The preferred photo-initiator is benzophenone, 2,4,6-trimethylbenzoyl diphenyl phosphine oxide, or a combination thereof.

Additionally, to adjust the composition to a viscosity suitable for coating or to a desired concentration, any appropriate solvent may be optionally added. Examples of which are sulfoxide solvents such as dimethyl sulfoxide (DMSO) and diethyl sulfoxide; formamide solvents such as N,N-dimethyl formamide (DMF) and N,N-diethyl formamide (DEF); acetamide solvents such as N,N-dimethyl acetamide (DMAc) and N,N-diethyl acetamide (DEAc); pyrrolidone solvents such as N-methyl-2-pyrrolidone (NMP) and N-ethyl-2-pyrrolidone (NEP); phenol solvents such as phenol, o-cresol, metacresol, p-cresol, dimethylphenol, halo-phenols, and pyrocatechol; ether solvents such as tetrahydrofuran (THF), dioxane, and dioxolane; alcohol solvents such as methanol, ethanol and butanol; cellosolve solvents such as butyl cellosolve; γ-butyrolactone (GBL), xylene; toluene; hexamethyl phosphoramide (RMPA); etc.

Furthermore, to enhance the physical properties of the photosensitive resin composition of the present invention after being post cured, an epoxy resin may be optionally added. Through the reaction of the epoxy resin with reactive functional groups remaining in the polyimide polymer, PSPI polymers with high stability can be obtained. The epoxy resin suitable for use in the present invention may be selected from a group consisting of bisphenol A EO-modified epoxy, bisphenol A PO-modified epoxy, o-cresol novolac epoxy, bisphenol A novolac epoxy, tris(hydroxyphenyl)methane novolac epoxy, novolac epoxy, glycidylamine type epoxy, tris(hydroxyphenyl)methane epoxy, alicyclic epoxy, and combinations thereof, but is not limited thereto. When the epoxy resin is added, it should be added in an amount of about 1 part by weight to about 50 parts by weight, and preferably about 5 parts by weight to about 40 parts by weight, based on 100 parts by weight of the photosensitive polyimide of the present invention.

The photosensitive resin composition of the present invention may be used in combination with a conventional lithographic process to form a desired coverlay layer on an FPC. Accordingly, the present invention also provides a method for forming a polyimide circuit, comprising:
applying the photosensitive resin composition of the present invention onto a substrate;
performing an exposure step on the substrate;
performing a development step on the substrate; and
thermally treating the substrate at a temperature ranging from about 100° C. to about 200° C.

Specifically, the photosensitive resin composition of the present invention is first applied onto a substrate (e.g., an FPC) in any appropriate manner to form a coating. The photosensitive resin composition of the present invention may be applied onto the substrate surface in a liquid form, or laminated to the substrate directly in a solid form. Subsequently, a lithographic process (i.e., an exposure step) is performed to define a circuit on the coating, and then a suitable development solution is used to remove unexposed portions of the coating. Finally, the substrate is post cured at a temperature of about 100° C. to about 200° C. to obtain the desired polyimide circuit.

Conventionally, the preparation of polyimide requires a thermal treatment (i.e., curing) temperature of up to about 300° C. to about 350° C. However, the photosensitive resin composition of the present invention can be cured at a temperature of about 100° C. to about 200° C. The lower curing temperature can prevent oxidation and deterioration of the circuit on the substrate, and reduce the cost. Instead of being a point of great concern of the present invention, the lithographic process used in the present invention is well known to those of ordinary skill in the art, and thus, will not be further described herein.

Hereinafter, the present invention will be further described with reference to examples thereof, with abbreviations set forth in the examples being defined as follows:
6FDA: 4,4′-hexafluoroisopropylidene-2,2-bis-(phthalic acid anhydride)
BAPA: 2,2′-bis(3-amino-4-hydroxyphenyl)propane
MEMG: bis(4-aminophenoxy)methane
DMDB: 2,2′-dimethylbiphenyl-4,4′-diamine
GMA: glycidyl methacrylate
2-TEA: 2-isocyanatoethyl acrylate
1-MI: 1-methylimidazole
HEMA: 2-hydroxyethyl methacrylate
HMC: 4′-hydroxy-4-methoxychalcone
IPDI: isophorone diisocyanate
PTZ: phenothiazine
NMP: N-methylpyrrolidone
TBAB: tetrabutylammonium bromide
MEHQ: hydroquinone monomethyl ether
DA1:

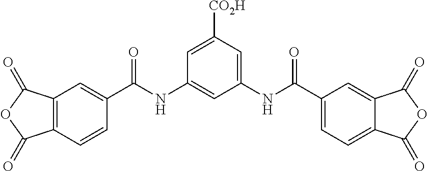

### (A) Synthesis of Polyimide with Hydroxyl

### Example 1

88.85 g (0.2 mol) of 6FDA, 28.63 g (0.1 mol) of BAPA and 23.03 g (0.1 mol) of MEMG were weighed and added into 300 mL of NMP. The resulting mixture was stirred at room temperature for 1 hour, heated to 50° C. and stirred for additional 4 hours. Next, 50 mL of xylene was added into the mixture, which was then dehydrated at 150° C. with a Dean-Stark device. After the dehydration was completed, polyimide with hydroxyl (P1) was obtained.

### Example 2

100.074 g (0.2 mol) of DA1 and 42.46 g (0.2 mol) of DMDB were weighed and added into 450 mL of NMP. The resulting mixture was stirred at room temperature for 1 hour, heated to 50° C. and stirred for additional 4 hours. Next, 50 mL of toluene was added into the mixture, which was then dehydrated at 130° C. with a Dean-Stark device. After the dehydration was completed, polyimide with hydroxyl (P2) was obtained.

### (B) Synthesis of Polyimide Modified by Diisocyanate

### Example 3

490 g of the polyimide P1 prepared in Example 1 was weighed, and 0.85 g of 1-MI, 6.51 g of HEMA, 11.12 g of IPDI and 0.11 g of PTZ were added thereto. The resulting mixture was stirred at room temperature for 1 hour. Then, with the temperature being elevated to 60° C., the mixture was stirred for an additional 6 hours to obtain photosensitive polyimide with hydroxyl modified by diisocyanate (P3).

### Example 4

490 g of the polyimide P1 prepared in Example 1 was weighed, and 0.85 g of 1-MI, 25.43 g of HMC, 22.23 g of IPDI and 0.11 g of PTZ were added thereto. The resulting mixture was stirred at room temperature for 1 hour. Then, with the temperature being elevated to 60° C., the mixture was stirred for an additional 6 hours to obtain photosensitive polyimide with hydroxyl modified by diisocyanate (P4).

### Example 5

142.5 g of the polyimide P2 prepared in Example 2 was weighed, and 7 g (0.05 mol) of 2-IEA, 0.05 g of 1-MI and 0.06 g of PTZ were added thereto. The resulting mixture was heated to 80° C. and stirred for 8 hours to obtain photosensitive polyimide P5.

### (C) Synthesis of Polyimide Modified by Epoxy Acrylate Compound

### Example 6

140.5 g of the polyimide P1 prepared in Example 1 was weighed, and 6.11 g (0.05 mol) of GMA, 0.015 g of TBAB and 0.06 g of MEHQ were added thereto. Then, the resulting mixture was heated to 90° C. and stirred for 12 hours to obtain photosensitive polyimide P6.

### Example 7

142.5 g of the polyimide P2 prepared in Example 2 was weighed, and 6.11 g (0.05 mol) of GMA, 0.015 g of TBAB and 0.06 g of MEHQ were added thereto. Then, the resulting mixture was heated to 90° C. and stirred for 12 hours to obtain photosensitive polyimide P7.

### (D) Polyimide Composition

The photosensitive polyimide products P3 to P7 prepared in Examples 3 to 7 were mixed with a photoinitiator, an acrylate monomer and an epoxy resin respectively to prepare the compositions shown in Table 1 below.

TABLE 1

| | | | Acrylate | |
|---|---|---|---|---|
| | Polyimide | ¹⁾Photoinitiator | monomer | Epoxy resin |
| | (parts by | (parts by | (parts by | (parts by |
| Composition | weight) | weight) | weight) | weight) |
| 1 | 100 (P3) | 0.2 | 10 (²⁾AM1) | |
| 2 | 100 (P4) | 0.2 | 10 (AM1) | |
| 3 | 100 (P5) | 0.2 | 10 (AM1) | |
| 4 | 100 (P6) | 0.2 | 10 (AM1) | |
| 5 | 100 (P7) | 0.2 | 10 (AM1) | |
| 6 | 100 (P3) | 0.2 | 20 (AM1) | |
| 7 | 100 (P3) | 0.2 | 30 (AM1) | |
| 8 | 100 (P3) | 0.2 | 40 (AM1) | |
| 9 | 100 (P3) | 0.2 | 20 (³⁾AM2) | |
| 10 | 100 (P3) | 0.2 | 20 (⁴⁾AM3) | |
| 11 | 100 (P3) | 0.2 | 20 (AM1) | 20 (⁵⁾EP1) |
| 12 | 100 (P3) | 0.2 | 20 (AM2) | 20 (EP1) |
| 13 | 100 (P3) | 0.2 | 20 (AM3) | 20 (EP1) |

¹⁾The photoinitiators are 2,4,6-trimethylbenzoyl diphenyl phosphine oxide;
²⁾AM1 is tripropylene glycol diacrylate;
³⁾AM2 is trimethylol propane ethoxylate triacrylate (3EOTMPTA);
⁴⁾AM3 is dipentaerythritol hexacrylate;
⁵⁾EP1 is bisphenol A EO-modified epoxy resin.

### (E) Measurement of Film Thickness and Film Shrinkage Before and After Development

The composition solutions as formulated above were coated onto respective copper substrates through a spin coating process respectively. Upon completion of the coating process, the substrates were put into an oven at a temperature of 60° C. to be baked for half an hour. Then, the substrates are taken out of the oven and film thickness values thereof were measured, with the measurement results recorded in Table 2 below.

The substrates were cooled to room temperature, and properties thereof after exposure and development were evaluated. The development conditions are as follows: the development solution was 1% Na₂CO₃, the development temperature was 30° C., and the development pressure was 1 to 2 kg/m². The evaluation results are also recorded in Table 2.

TABLE 2

| | | Difference in film |
|---|---|---|
| | Film thickness | thickness before and after |
| Composition | (μm) | development (μm) |
| 1 | 25 | 3 |
| 2 | 25 | 4 |
| 3 | 25 | 4 |
| 4 | 25 | 4 |
| 5 | 25 | 5 |
| 6 | 25 | 4 |
| 7 | 25 | 4 |
| 8 | 25 | 4 |
| 9 | 25 | 4 |
| 10 | 25 | 3 |
| 11 | 25 | 2 |
| 12 | 25 | 2 |
| 13 | 25 | 1 |

As can be seen from Table 2, the photosensitive resin composition of the present invention can still maintain a film thickness of 25 μm after being baked, which demonstrates a good molecular structure of the photosensitive resin composition. Also, the photosensitive resin composition of the present invention exhibits a difference in film thickness of less than 5 μm before and after development. Therefore, it can effectively prevent distortion of the photoresist pattern when being used as a photo resistor in practice.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A photosensitive resin composition comprising:
a photosensitive polyimide of formula (I): 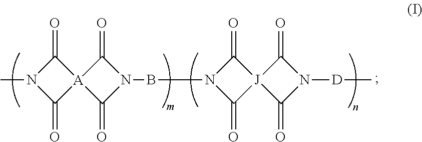
an acrylate monomer; and
a photoinitiator,
wherein,
A and J are independently a tetravalent organic group;
B and D are independently a divalent organic group;
n is 0 or an integer of greater than 0;
m is an integer of greater than 0; and
at least one of A and B has one or more photosensitive group(s) G* selected from a group consisting of: 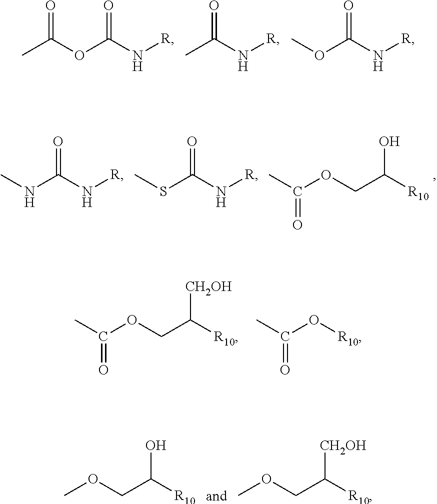
wherein,
R is an unsaturated group with —C═C— or selected from a group consisting of: 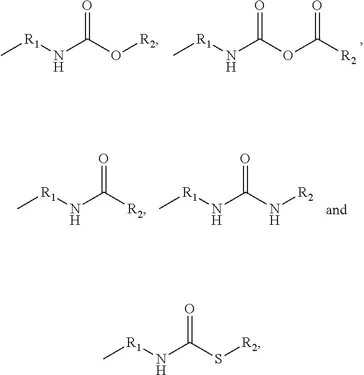
R₁ is a substituted or unsubstituted, saturated or unsaturated C₁-C₂₀ organic group, R₂ is an unsaturated group with —C═C—; and R₁₀ is an unsaturated group with an acrylate group.

2. The composition of claim 1, wherein the unsaturated group with —C═C— is selected from a group consisting of: 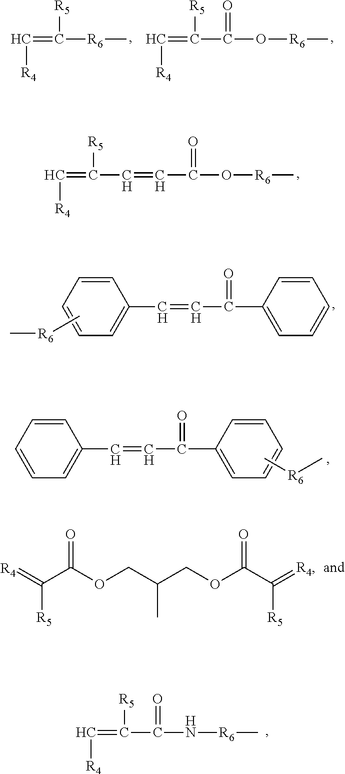
wherein,
R₄ and R₅ are independently H, or a substituted or unsubstituted C₁-C₇ organic group; and
R₆ is a covalent bond, —O—, or a substituted or unsubstituted C₁-C₂₀ organic group.

3. The composition of claim 1, wherein R₁ is selected from a group consisting of: 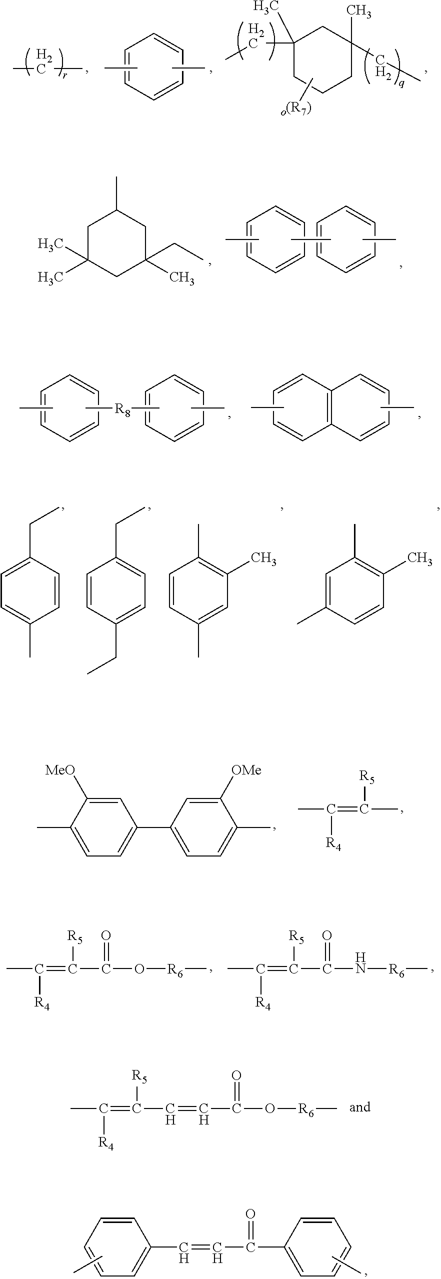
wherein,
r is an integer of greater than 0;
o, p and q are independently 0 or an integer of greater than 0;
R₄, R₅ and R₆ have the meanings defined in claim 2;
R₇ is H or a substituted or unsubstituted C₁-C₁₂ organic group; and
R₈ is a covalent bond or selected from a group consisting of:

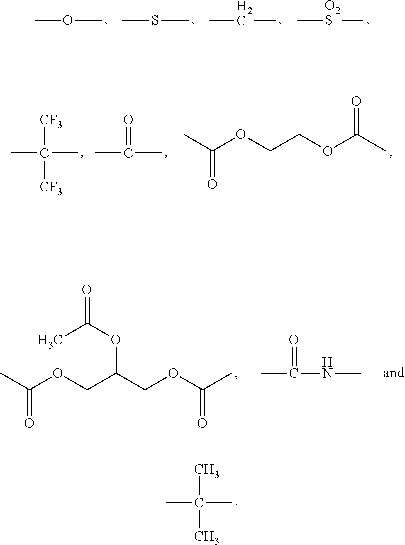

4. The composition of claim 1, wherein the unsaturated group with an acrylate group is 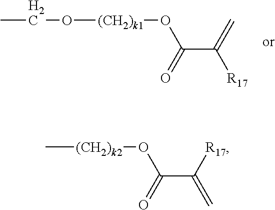
wherein R₁₇ is H or methyl, and K1 and K2 are independently an integer ranging from 0 to 6.

5. The composition of claim 1, wherein A is selected from a group consisting of: 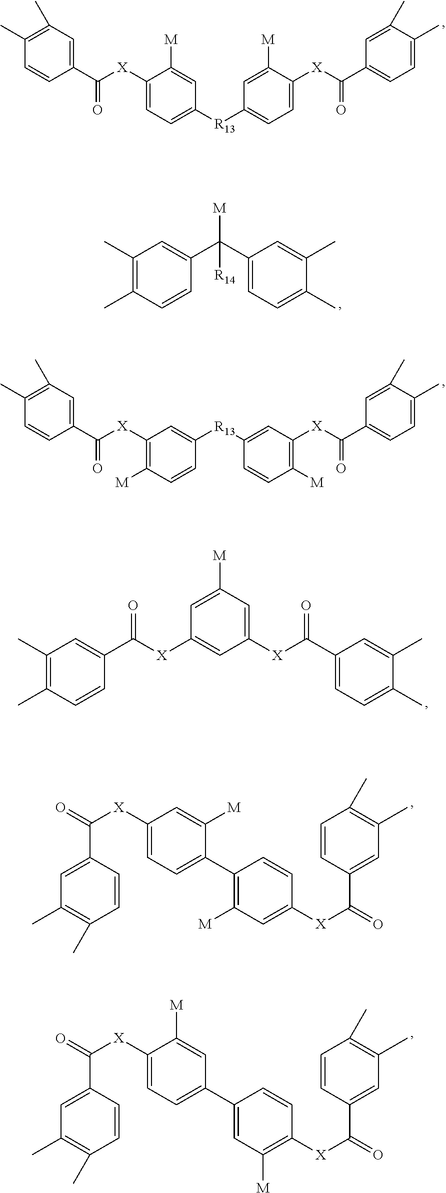 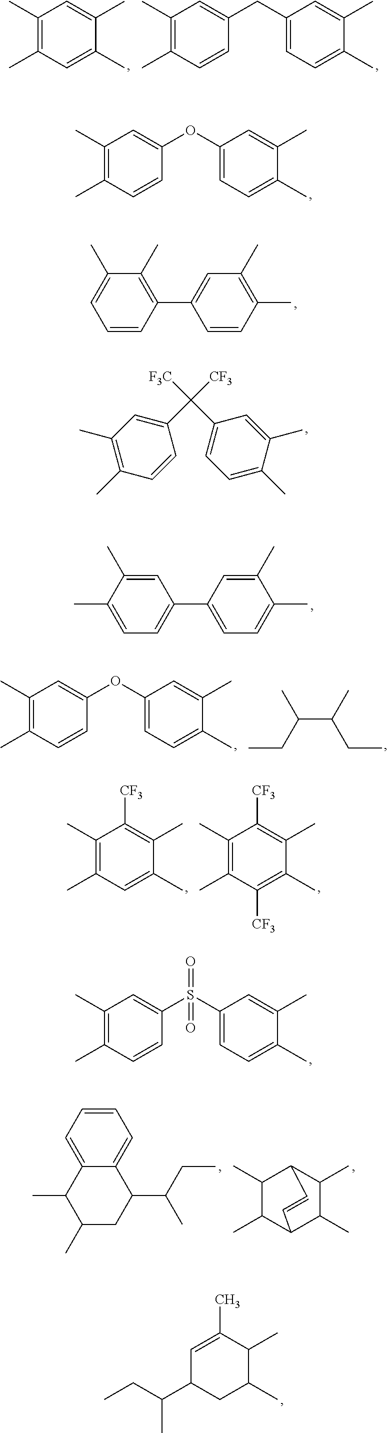 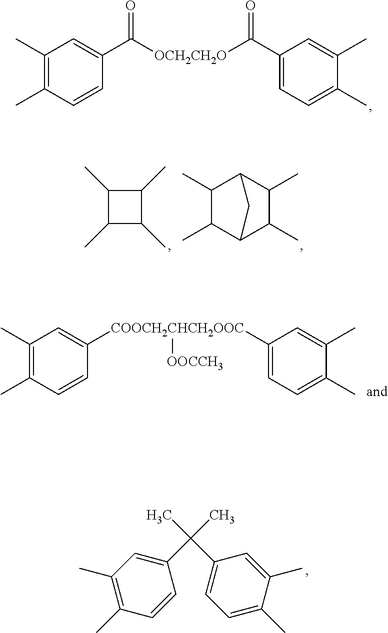
wherein,
M is photosensitive group G*, H, COOH, OH, NH₂ or SH, and G* has the meanings defined in claim 1;
R₁₃ is —CH₂—, —O—, —S—, —CO—, —SO₂—, —C(CH₃)₂— or —C(CF₃)₂—;
R₁₄ is —H or —CH₃; and
X is —O—, —NH— or —S—.

6. The composition of claim 1, wherein J is selected from a group consisting of: 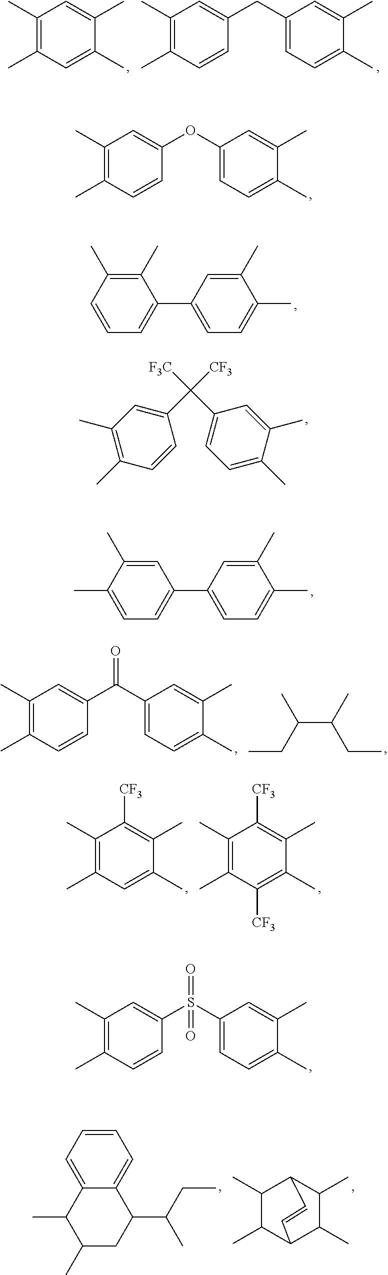 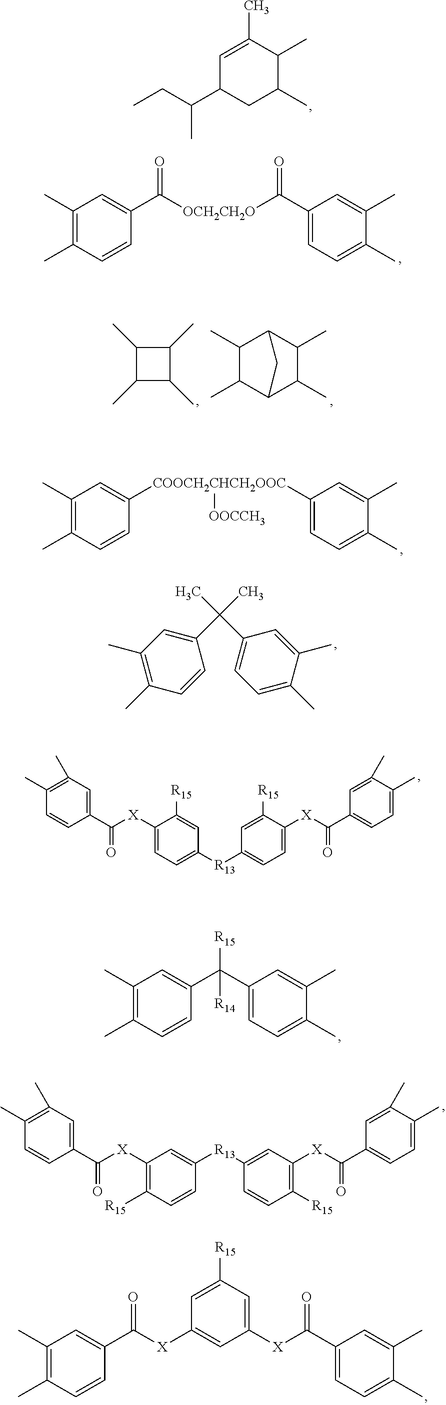 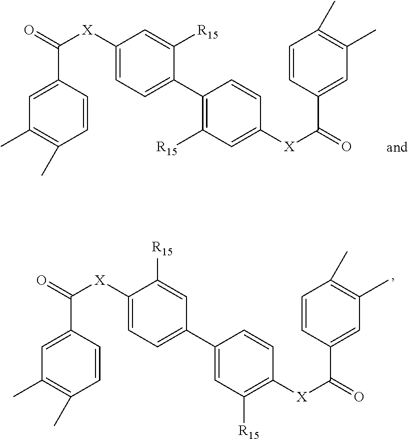
wherein,
R₁₃, R₁₄ and X have the meanings defined in claim 5; and
R₁₅ is —H, —OH, —COOH, —NH₂ or —SH.

7. The composition of claim 1, wherein B is selected from a group consisting of: 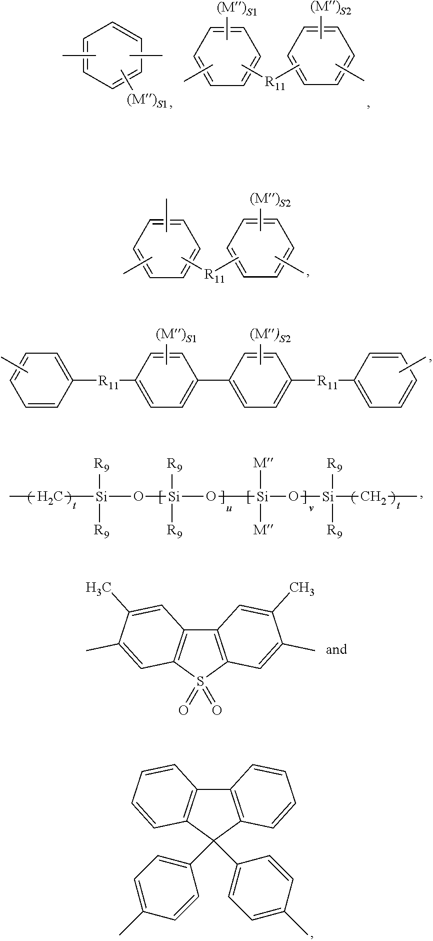
wherein,
M″ is H, C₁-C₄ alkyl, C₁-C₄ perfluoroalkyl, methoxy, ethoxy, halogen, OH, COOH, NH₂, SH or photosensitive group G*, wherein G* has the meanings defined in claim 1;
S1 and S2 are independently an integer ranging from 1 to 4;
t is an integer of greater than 0;
u is 0 or an integer of greater than 0;
v is 0 or an integer of greater than 0;
R₉ is H, methyl, ethyl or phenyl; and
R₁₁ is a covalent bond or selected from a group consisting of: 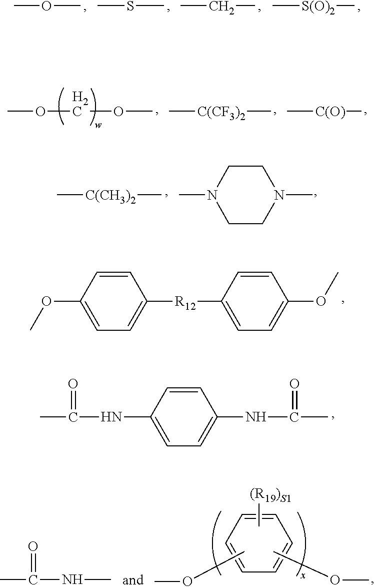
wherein, w and x are independently an integer of greater than 0; R₁₂ is a covalent bond, —SO₂—, —C(O)—, —C(CF₃)₂—, or a substituted or unsubstituted C₁-C₁₈ organic group, and R₁₉ is H or C₁-C₄ alkyl.

8. The composition of claim 1, wherein D is selected from a group consisting of: 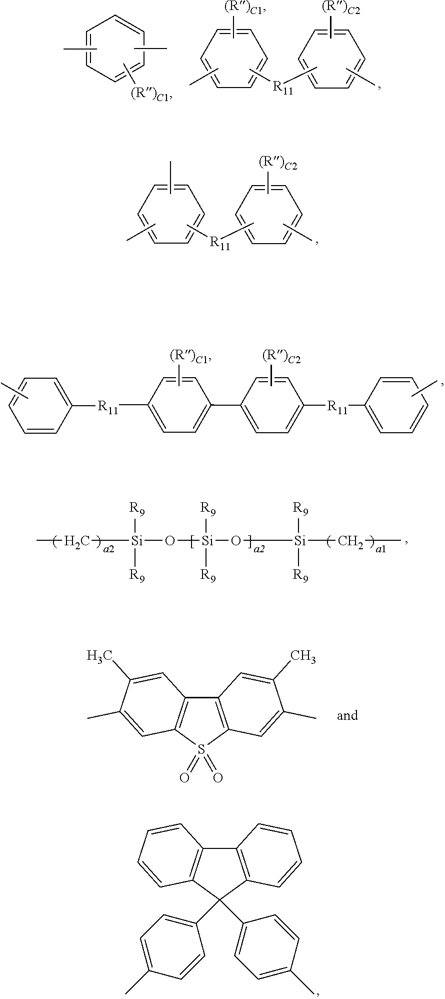
wherein,
R″ is H, C₁-C₄ alkyl, C₁-C₄ perfluoroalkyl, methoxy, ethoxy, halogen, OH, COOH, NH₂, or SH;
C1 and C2 are independently an integer ranging from 1 to 4;
a1 and a2 are independently an integer of greater than 0; and
R₉ and R₁₁ have the meanings defined in claim 7.

9. The composition of claim 1, wherein the amount of the acrylate monomer is about 5 parts by weight to about 80 parts by weight, based on 100 parts by weight of the photosensitive polyimide.

10. The composition of claim 1, wherein the ratio of m and n is about 0.04 to about 25.

11. The composition of claim 1, wherein the amount of the photoinitiator is about 0.01 parts by weight to about 20 parts by weight, based on 100 parts by weight of the photosensitive polyimide.

12. The composition of claim 1, wherein the photoinitiator comprises a compound which can absorb a light having a wavelength ranging from about 350 nm to about 500 nm to generate free radicals.

13. The composition of claim 1, further comprising an epoxy resin.

14. A method for forming a polyimide circuit, comprising:
applying the composition of claim 1 onto a substrate;
performing an exposure step on the substrate;
performing a development step on the substrate; and
thermally treating the substrate at a temperature ranging from about 100° C. to about 200° C.
